(19) United States
(12) Patent Application Publication
(10) Pub. No.: US 2025/0268069 A1
(43) Pub. Date: Aug. 21, 2025

(54) DISPLAY APPARATUS, APPARATUS FOR MANUFACTURING THE DISPLAY APPARATUS, AND METHOD OF MANUFACTURING THE DISPLAY APPARATUS

(71) Applicant: SAMSUNG DISPLAY CO., LTD., Yongin-si (KR)

(72) Inventors: Soyeon JOO, Yongin-si (KR); Shinya ONOUE, Yongin-si (KR); Jongdeok PARK, Yongin-si (KR); Jaeyoung SIM, Yongin-si (KR)

(21) Appl. No.: 18/940,953

(22) Filed: Nov. 8, 2024

(30) Foreign Application Priority Data
Feb. 19, 2024 (KR) 10-2024-0023660

(51) Int. Cl. H10K 59/80; H01L 21/687; H10K 59/12; H10K 71/40

(52) U.S. Cl. CPC H10K 59/873; H01L 21/68735; H10K 59/1201; H10K 71/40

(57) ABSTRACT

A display apparatus including a display panel. The display panel comprises a substrate including a first area, a second area, and a bent area that is in a bent state. The bent area connects the first area to the second area. A first protective layer is disposed inside the bent area of the substrate. A second protective layer is disposed on at least a portion of an edge of the substrate and at least one surface of the bent area of the substrate.

### CROSS-REFERENCE TO RELATED APPLICATION

This application claims priority under 35 U.S.C. § 119 to Korean Patent Application No. 10-2024-0023660, filed on Feb. 19, 2024 in the Korean Intellectual Property Office, the disclosure of which is incorporated by reference in its entirety herein.

### 1. TECHNICAL FIELD

One or more embodiments relate to an apparatus and a method, and more particularly, to a display apparatus, an apparatus for manufacturing the display apparatus, and a method of manufacturing the display apparatus.

### 2. DISCUSSION OF RELATED ART

A variety of mobile electronic apparatuses are widely used by consumers. For example, tablet personal computers (PCs) have been widely used as well as miniaturized electronic apparatuses such as mobile phones.

Mobile electronic apparatuses may include a display apparatus to support various functions, such as to provide a user with visual information by generating images. Recently, as the parts configured to drive a display apparatus have been miniaturized, the proportion of the display apparatus in an electronic apparatus has gradually increased. Research has been conducted concerning a display apparatus that may be bent to form a preset angle from a flat state.

### SUMMARY

A display apparatus includes a display panel. The display panel may be inserted into a housing. Impacts may be applied to the edge of the display panel due to contact between the display panel and the housing. Accordingly, the display panel may be damaged. Embodiments provide a display apparatus configured to not only prevent destruction of a display panel received inside a housing but also protect a bent portion of the display panel, an apparatus for manufacturing the display apparatus, and a method of manufacturing the display apparatus.

Additional aspects will be set forth in part in the description which follows and, in part, will be apparent from the description, or may be learned by practice of the presented embodiments of the disclosure.

According to an embodiment of the present disclosure, a display apparatus including a display panel. The display panel comprises a substrate including a first area, a second area, and a bent area that is in a bent state. The bent area connects the first area to the second area. A first protective layer is disposed inside the bent area of the substrate. A second protective layer is disposed on at least a portion of an edge of the substrate and at least one surface of the bent area of the substrate.

In an embodiment, the first protective layer and the second protective layer may each include a photocurable resin.

In an embodiment, the photocurable resin may be cured by light with a peak top of a wavelength in a range of about 450 nm to about 500 nm.

In an embodiment, the photocurable resin may include at least one of diphenyl (2,4,6-trimethylbenzoyl) phosphine oxide (2,4,6-trimethylbenzoyldiphenyl phosphine oxide), ethyl (2:4 6-trimethylbenzoyl)phenylphosphophinate (ethyl (2,4,6-trimethylbenzoyl)phenylphosphinate), bis-acylphosphine oxides, and bis(cyclopentadienyl)-bis(2,6-difluoro-3-(pyrrol-1-yl))-phenyl) titanium (bis(cyclopentadienyl)-bis [2,6-difluoro-3-(pyrrol-1-yl)-phenyl]titaninum) and camphoquinone (CQ).

In an embodiment, the display apparatus may further include a bracket. The bracket is arranged to receive the display panel.

In an embodiment, the bracket may include an injection hole that is arranged to receive the photocurable resin.

In an embodiment, the bracket may include a transparent material.

In an embodiment, the second protective layer may be connected to the first protective layer.

According to an embodiment of the present disclosure, an apparatus for manufacturing a display apparatus includes a first jig. A second jig is arranged to receive a display panel thereon. The second jig faces the first jig. A mold is disposed between the first jig and the second jig. The mold is selectively coupled to the first jig. The mold and the second jig together forming a space in an edge portion of the display panel. The first jig and the mold include a transparent material.

According to an embodiment, one of the first jig and the second jig may include a coupling portion. Another of the first jig and the second jig may include a first receiver that is arranged to receive the coupling portion.

In an embodiment, the mold may include a second receiver that is arranged to receive the coupling portion.

In an embodiment, the first jig and the mold may include an injector that is arranged to receive a photocurable resin in the space.

In an embodiment, the photocurable resin may be cured by light with a peak top of a wavelength in a range of about 450 nm to about 500 nm.

In an embodiment, the photocurable resin may include at least one of diphenyl (2,4,6-trimethylbenzoyl) phosphine oxide (2,4,6-trimethylbenzoyldiphenyl phosphine oxide), ethyl (2:4 6-trimethylbenzoyl)phenylphosphophinate (ethyl (2,4,6-trimethylbenzoyl)phenylphosphinate), bis-acylphosphine oxides, and bis(cyclopentadienyl)-bis(2,6-difluoro-3-(pyrrol-1-yl))-phenyl) titanium (bis(cyclopentadienyl)-bis [2,6-difluoro-3-(pyrrol-1-yl)-phenyl]titaninum) and camphoquinone (CQ).

In an embodiment, the apparatus may further include a light source disposed on a lateral surface of the first jig and the mold and irradiating light to the space.

In an embodiment, the light source may irradiate visible light towards the first jig and the mold.

According to an embodiment of the present disclosure, a method of manufacturing a display apparatus includes disposing, on a second jig, a display panel having a bent portion that is in a bent state, disposing, on the display panel, a first jig and a mold to form a first space in at least one edge of the display panel, supplying photocurable resin into the first space, and curing the photocurable resin by irradiating light to the first space.

In an embodiment, the photocurable resin may be cured by light with a peak top of a wavelength in a range of about 450 nm to about 500 nm.

In an embodiment, the photocurable resin may include at least one of diphenyl (2,4,6-trimethylbenzoyl) phosphine oxide (2,4,6-trimethylbenzoyldiphenyl phosphine oxide), ethyl (2:4 6-trimethylbenzoyl)phenylphosphophinate (ethyl (2,4,6-trimethylbenzoyl)phenylphosphinate), bis-acylphosphine oxides, and bis(cyclopentadienyl)-bis(2,6-difluoro-3-(pyrrol-1-yl))-phenyl) titanium (bis(cyclopentadienyl)-bis [2,6-difluoro-3-(pyrrol-1-yl)-phenyl]titaninum) and camphoquinone (CQ).

In an embodiment, the light may be irradiated from a lateral surface of the display panel.

In an embodiment, the method may further include injecting the photocurable resin to a second space between upper and lower surfaces of the bent portion of the display panel and the display panel facing each other.

In an embodiment, the photocurable resin supplied into the first space and the photocurable resin injected into the second space may be cured and connected to each other.

According to an embodiment of the present disclosure, a method of manufacturing a display apparatus includes disposing a display panel inside a bracket to form a first space defined by at least one edge of the display panel, the bracket and a cover member of the display panel. A photocurable resin is supplied into the first space. The photocurable resin is cured by irradiating light to the first space.

In an embodiment, the photocurable resin may be cured by light with a peak top of a wavelength in a range of about 450 nm to about 500 nm.

In an embodiment, the photocurable resin may include at least one of diphenyl (2,4,6-trimethylbenzoyl) phosphine oxide (2,4,6-trimethylbenzoyldiphenyl phosphine oxide), ethyl (2:4 6-trimethylbenzoyl)phenylphosphophinate (ethyl (2,4,6-trimethylbenzoyl)phenylphosphinate), bis-acylphosphine oxides, and bis(cyclopentadienyl)-bis(2,6-difluoro-3-(pyrrol-1-yl))-phenyl) titanium (bis(cyclopentadienyl)-bis [2,6-difluoro-3-(pyrrol-1-yl)-phenyl]titaninum) and camphoquinone (CQ).

In an embodiment, the light may be irradiated from a lateral surface of the display panel.

In an embodiment, the method may further include injecting the photocurable resin into a second space between opposing upper and lower surfaces of a bent portion of the display panel that is in a bent state.

In an embodiment, the photocurable resin supplied into the first space and the photocurable resin injected into the second space may be cured and connected to each other.

In an embodiment, the bracket may include a transparent material.

These and/or other aspects will become apparent and more readily appreciated from the following detailed description of the embodiments, the accompanying drawings, and claims.

These general and specific aspects may be implemented by using a system, a method, a computer program, or a combination of a certain system, method, and computer program.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display apparatus according to an embodiment of the present disclosure;

FIG. 2 is a schematic exploded perspective view of the display apparatus shown in FIG. 1 according to an embodiment of the present disclosure;

FIG. 3A is a schematic cross-sectional view of a display panel, taken along line III-III′ of FIG. 2 according to an embodiment of the present disclosure;

FIG. 3B is an enlarged cross-sectional view of a region A shown in FIG. 3A according to an embodiment of the present disclosure;

FIG. 4 is a schematic plan view of the display panel shown in FIG. 2 according to an embodiment of the present disclosure;

FIG. 5 is a schematic perspective view of a bent state of at least a portion of the display panel shown in FIG. 4 according to an embodiment of the present disclosure;

FIG. 6 is a cross-sectional view of a display panel, taken along line VI-VI′ of FIG. 4 according to an embodiment of the present disclosure;

FIGS. 7A and 7B are circuit diagrams of a circuit of the display panel shown in FIG. 6 according to embodiments of the present disclosure;

FIG. 8 is a schematic perspective view of an apparatus for manufacturing a display apparatus according to an embodiment of the present disclosure;

FIG. 9 is a schematic cross-sectional view of the apparatus for manufacturing a display apparatus shown in FIG. 8 according to an embodiment of the present disclosure;

FIG. 10A to 10C are schematic cross-sectional views showing a method of manufacturing a display apparatus according to embodiments of the present disclosure; and

FIG. 11 is a schematic cross-sectional view of a portion of a display apparatus according to an embodiment of the present disclosure.

### DETAILED DESCRIPTION OF EMBODIMENTS

Reference will now be made in detail to embodiments of the present disclosure, examples of which are illustrated in the accompanying drawings, wherein like reference numerals refer to like elements throughout. In this regard, the present embodiments may have different forms and should not be construed as being limited to the descriptions set forth herein. Accordingly, embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the present disclosure, and methods for achieving them will be clarified with reference to embodiments described below in detail with reference to the drawings. However, the present disclosure is not limited to the described embodiments and may be embodied in various forms.

Hereinafter, embodiments will be described with reference to the accompanying drawings, wherein like reference numerals refer to like elements throughout and a repeated description thereof is omitted.

While such terms as “first” and “second” may be used to describe various elements, such elements must not be limited to the above terms. The above terms are used to distinguish one element from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or elements but do not preclude the addition of one or more other features or elements.

It will be further understood that, when a layer, region, or element is referred to as being “on” another layer, region, or element, it can be directly or indirectly on the other layer, region, or element. For example, intervening layers, regions, or elements may be present. When a layer, region, or element is referred to as being “directly on” another layer, region, or element, no intervening layers, regions or elements may be present.

Sizes of elements in the drawings may be exaggerated or reduced for convenience of explanation. As an example, the size and thickness of each element shown in the drawings may be arbitrarily represented for convenience of description, and thus, embodiments of the present disclosure are not necessarily limited thereto.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different orientations that are not perpendicular to one another.

In the case where a certain embodiment may be implemented differently, a specific process order may be performed in the order different from the described order. As an example, two processes successively described may be simultaneously performed substantially and performed in the opposite order.

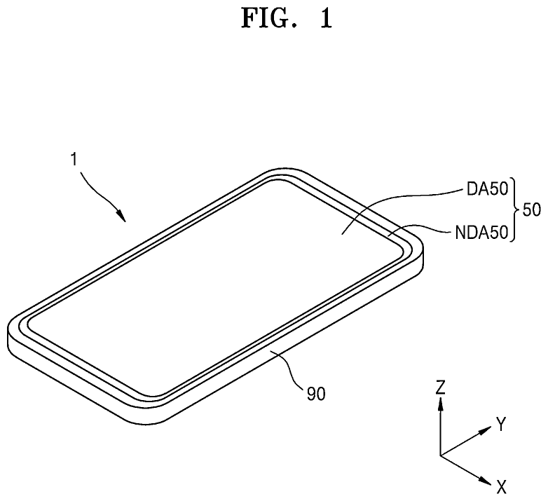

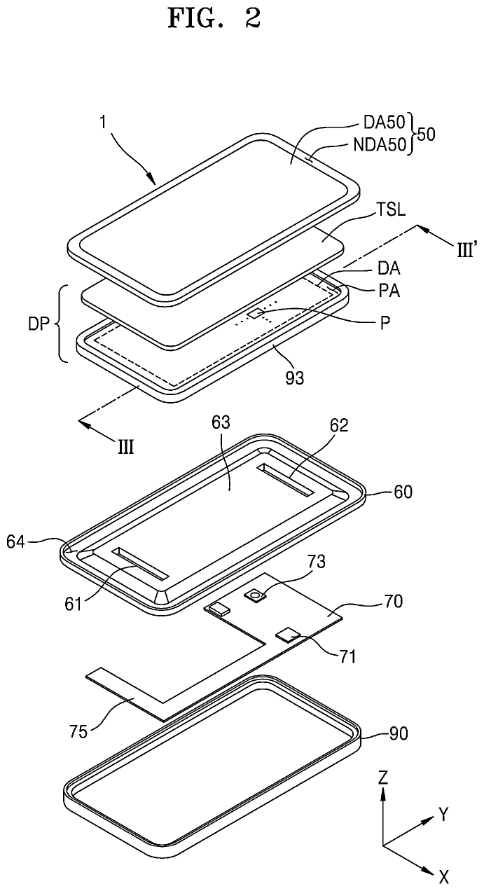

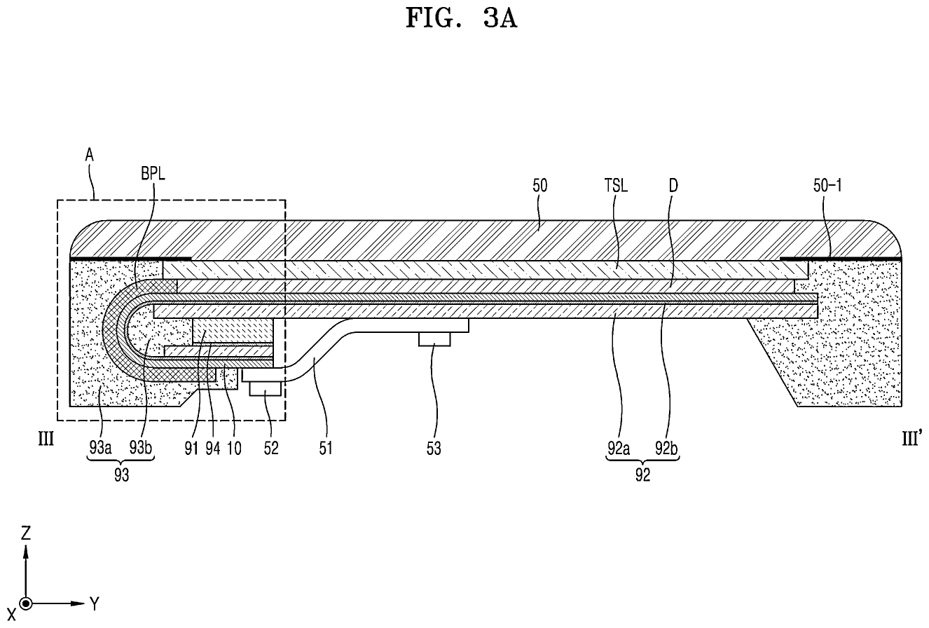

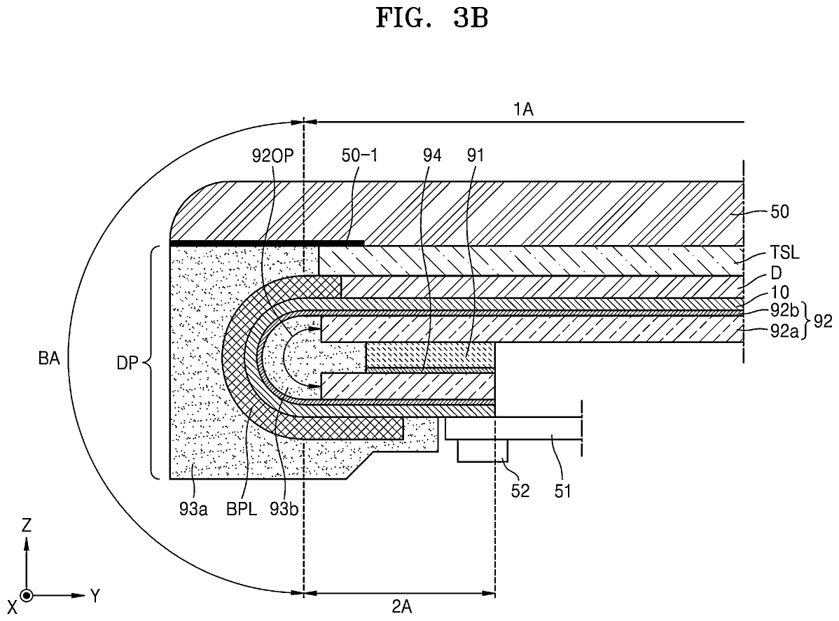

FIG. 1 is a schematic perspective view of a display apparatus 1 according to an embodiment. FIG. 2 is a schematic exploded perspective view of the display apparatus 1 shown in FIG. 1. FIG. 3A is a schematic cross-sectional view of a display panel, taken along line III-III′ of FIG. 2. FIG. 3B is an enlarged cross-sectional view of a region A shown in FIG. 3A.

Referring to FIGS. 1 to 3B, in an embodiment the display apparatus 1 may include an apparatus for displaying at least one moving image and/or still image and may be used as a display screen of various products including televisions, notebook computers, monitors, advertisement boards, Internet of things (IoTs) device as well as portable electronic apparatuses including mobile phones, smartphones, tablet personal computers (PCs), mobile communication terminals, electronic organizers, electronic books, portable multimedia players (PMPs), navigations, or ultra mobile personal computers (UMPCs). In addition, the display apparatus 1 may be used in wearable devices including smartwatches, watchphones, glasses-type displays, or head-mounted displays (HMDs). In addition, the display apparatus 1 may be used in a display screen in instrument panels for automobiles, center fascias for automobiles, or center information displays (CIDs) arranged on a dashboard, room mirror displays that replace side mirrors of automobiles, and displays of an entertainment system arranged on the backside of front seats for backseat passengers in automobiles. An electronic apparatus includes one of televisions, notebook computers, monitors, advertisement boards, Internet of things (IoTs) device, mobile phones, smartphones, tablet personal computers (PCs), mobile communication terminals, electronic organizers, electronic books, portable multimedia players (PMPs), navigations, ultra mobile personal computers (UMPCs), smartwatches, watchphones, glasses-type displays, head-mounted displays, instrument panels for automobiles, center fascias for automobiles, center information displays (CIDs) arranged on a dashboard, room mirror displays that replace side mirrors of automobiles or the entertainment system arranged on the backside of front seats for backseat passengers in automobiles.

In an embodiment, the display apparatus 1 may include a display panel DP, a display circuit board 51, a cover member 50, a bracket 60, a main circuit board 70, and a lower cover 90.

The cover member 50 may be disposed on the display panel DP (e.g., in the Z direction). In an embodiment, the cover member 50 may cover the upper portion of the display panel DP. Accordingly, the cover member 50 may be configured to protect the upper surface of the display panel DP.

In an embodiment, the cover member 50 may include a transmissive cover portion DA50 corresponding to (e.g., overlapping in the Z direction) the display panel DP, and a light-blocking cover portion NDA50 corresponding to (e.g., overlapping in the Z direction) a region other than the display panel DP. The light-blocking cover portion NDA50 may include an opaque material configured to block light. In an embodiment, the light-blocking cover portion NDA50 may include a pattern that may be viewed to a user while images are not displayed.

The display panel DP may be disposed under the cover member 50. The display panel DP may overlap the transmissive cover portion DA50 of the cover member 50 (e.g., in the Z direction).

In an embodiment, the cover member 50 may include a cover window and a protective member. In an embodiment, the cover window may include a transparent material. In this embodiment, the cover window may include glass, synthetic resin of a transparent material, and the like. The cover window may include at least one layer.

In an embodiment, the protective member may be disposed on the upper surface of the cover window to prevent or reduce the occurrence of scratches and the like in the cover window. In an embodiment, an opaque layer 50-1 may be disposed on at least one of the cover window and a portion of the protective member. In an embodiment, the opaque layer 50-1 may be disposed on the edge of the cover window or the edge of the protective member. The opaque layer 50-1 may be configured to block light and be disposed on the light-blocking cover portion NDA50 of the cover member 50.

The display panel DP may include a display area DA and a peripheral area PA around the display area DA (e.g., in the X and/or Y directions). Images generated by the display panel DP are displayed in the display area DA. Sub-pixels P each including a display element may be arranged in the display area DA. In this embodiment, the sub-pixels P may be provided in plurality to be spaced apart from each other. Portions (e.g., groups) of the plurality of sub-pixels P may be configured to emit light of different colors from each other. The display apparatus 1 may be configured to display images using light emitted from pixels P arranged in the display area DA. In an embodiment, the peripheral area PA may be a region in which the sub-pixels P are not arranged. However, embodiments of the present disclosure are not necessarily limited thereto.

The display panel DP is configured to display (e.g., output) information processed by the display apparatus 1. As an example, in an embodiment the display panel DP may display execution screen information of an application driven in the display apparatus 1, or user interface (UI) and graphic user interface (GUI) information corresponding to the execution screen information. In an embodiment, the display panel DP may include a display layer and a touch sensor layer. The display layer displays images, and the touch sensor layer senses a user's touch input. Accordingly, the display panel DP may serve as an input unit that provides an input interface between the display apparatus 1 and a user, and simultaneously, serves as an output unit that provides an output interface between the display apparatus 1 and a user.

Hereinafter, although an organic light-emitting display apparatus is described as an example of the display apparatus 1 according to an embodiment, the display apparatus 1 according to embodiments of the present disclosure are not necessarily limited thereto. In an embodiment, the display apparatus 1 according to an embodiment of the present disclosure may be an inorganic light-emitting display apparatus or a quantum-dot light-emitting display apparatus. As an example, an emission layer of a display element provided to the display apparatus 1 may include an organic material, an inorganic material, quantum dots, an organic material and quantum dots, or an inorganic material and quantum dots.

In an embodiment, the display panel DP may be a flexible display panel which has flexibility and thus is easily bendable, foldable, or rollable. As an example, the display panel DP may include a foldable display panel that is foldable into a folded state and unfoldable from the folded state into an unfolded state, a curved display panel that has a curved display surface, a bended display panel in which a region except a display surface is bent, a rollable display panel that is rollable and unrollable, and a stretchable display panel that is stretchable. However, embodiments of the present disclosure are not necessarily limited thereto. For example, in an embodiment, the display panel DP may be a rigid display panel that has rigidity and is not easily bent.

In an embodiment, the display panel DP may include a substrate 10, a display layer D disposed on the substrate 10 (e.g., disposed directly thereon), a touch sensor layer TSL disposed on the display layer D (e.g., disposed directly thereon), and a protective layer 93 arranged to surround the lateral surfaces of the substrate 10 and the display layer D. In this embodiment, at least a portion of the substrate 10 may be bent (e.g., be bendable). The protective layer 93 may include a first protective layer 93a and a second protective layer 93b. The first protective layer 93a is disposed on at least a portion of the edge of the substrate 10 and the display layer D, and the second protective layer 93b is disposed inside the bent portion of the substrate 10. For example, as shown in FIG. 3B, the first protective layer 93a may be disposed on at least a portion of an edge of the substrate 10 and at least one surface of the bent area BA. The second protective layer 93b may be disposed inside the bent portion of the substrate 10 between opposing upper and lower sides of the substrate 10 that is in a bent orientation (e.g., a bent state) in the bent area BA. In an embodiment, the first protective layer 93a and the second protective layer 93b may be connected to each other. The second protective layer 93b may be arranged between a first area 1A, a second area 2A, and a bent area BA. Hereinafter, for convenience of description, an embodiment in which the first protective layer 93a surrounds all of (e.g., an entirety of) the edge of the substrate 10 is mainly described in detail. In this embodiment, the first protective layer 93a may be arranged to surround not only the edge of the substrate 10 but also the outer surface of a bending protective layer BPL.

In an embodiment, the protective layer 93 may include photocurable resin. In this embodiment, the photocurable resin may be cured when light is irradiated thereto. For example, in an embodiment the photocurable resin may be cured by using light with a peak top of a wavelength in a range of about 450 nm to about 500 nm. In a comparative embodiment in which light with a peak top of a wavelength less than about 450 nm is irradiated to the photocurable resin, since the light cannot pass through the substrate 10, the light cannot cure the second protective layer 93b together with the first protective layer 93a. In addition, in a comparative embodiment in which light with a peak top of a wavelength greater than about 500 nm is irradiated, since the light includes excessive heat, destruction of the display panel DP and the like may be caused by the heat.

In an embodiment, the photocurable resin may include a photoinitiator. In this embodiment, the photoinitiator of the photocurable resin may include at least one of diphenyl (2,4,6-trimethylbenzoyl) phosphine oxide (2,4,6-trimethylbenzoyldiphenyl phosphine oxide), ethyl (2:4 6-trimethylbenzoyl)phenylphosphophinate (ethyl (2,4,6-trimethylbenzoyl)phenylphosphinate), bis-acylphosphine oxides, and bis(cyclopentadienyl)-bis(2,6-difluoro-3-(pyrrol-1-yl))-phenyl) titanium (bis(cyclopentadienyl)-bis [2,6-difluoro-3-(pyrrol-1-yl)-phenyl]titaninum) and camphoquinone (CQ).

The display panel DP may be disposed under the cover member 50. In an embodiment, the display panel DP may include a protective film 92 and an adhesive member 94 disposed under the substrate 10. In an embodiment, the protective film 92 may include a protective film base 92a and an adhesive layer 92b. In an embodiment, the protective film base 92a may include polyethylene terephthalate (PET) or polyimide (PI). In addition, the adhesive layer 92b may include various adhesive materials. In an embodiment, the adhesive layer 92b may be disposed on the entire surface of the substrate 10, and after the adhesive layer 92b is disposed on the substrate 10, a portion of the protective film base 92a may be removed to form an opening 92OP. However, embodiments of the present disclosure are not necessarily limited thereto. For example, in an embodiment, the opening 92OP may be formed by removing a portion of the protective film base 92a and a portion of the adhesive layer 92b. In this embodiment, neither the protective film base 92a nor the adhesive layer 92b may be present in the opening 92OP.

In addition, the display panel DP may include a cushion layer 91 disposed between the protective film bases 92a on opposing upper and lower sides of the substrate 10 when the display panel DP has a bent orientation (e.g., a bent state) in the bent area BA. In this embodiment, the cushion layer 91 may be disposed in a region where the first area 1A and the second area 2A face each other (e.g., in the Z direction). For example, in an embodiment the cushion layer 91 may be disposed to be in direct contact with a portion of the protective film base 92a in the first area 1A and be in indirect contact with a portion on the protective film base 92a in the second area 2A. The substrate 10 and the like are bent, and then the cushion layer 91 may be disposed in a space where the first area 1A and the second area 2A are spaced apart from each other (e.g., in the Z direction), thereby supporting the display panel DP and absorbing impacts. In an embodiment, the cushion layer 91 may include an elastic material. In an embodiment, the cushion layer 91 may be attached to the protective film base 92a before the bending operation. However, embodiments of the present disclosure are not necessarily limited thereto.

In an embodiment, the adhesive member 94 may be disposed between the cushion layer 91 and the protective film base 92a in the second area 2A to fix the cushion layer 91 to the protective film base 92a.

In an embodiment, the display panel DP may be connected to the display circuit board 51 using an anisotropic conductive film.

A touch sensor driver 53 may be disposed on (e.g., disposed directly thereon) the display circuit board 51. In an embodiment, a display driver 52 may be disposed directly on the substrate 10 of the display panel DP. However, embodiments of the present disclosure are not necessarily limited thereto. For example, in an embodiment, the display driver 52 may be disposed on the display circuit board 51. Hereinafter, for convenience of description, an embodiment in which the display driver 52 is disposed on the display circuit board 51 is mainly described in detail.

In an embodiment, the substrate 10 of the display panel DP may be at least partially bent. In this embodiment, the bending protective layer BPL may be disposed in the bent portion of the substrate 10 to prevent cracks and the like of the substrate 10. In an embodiment, the bending protective layer BPL may include, for example, polymer resin such as polyethyleneterephthalate (PET), polyimide (PI), and the like.

In an embodiment, the display apparatus 1 may include a panel protective member disposed under (e.g., directly thereunder) the display panel DP.

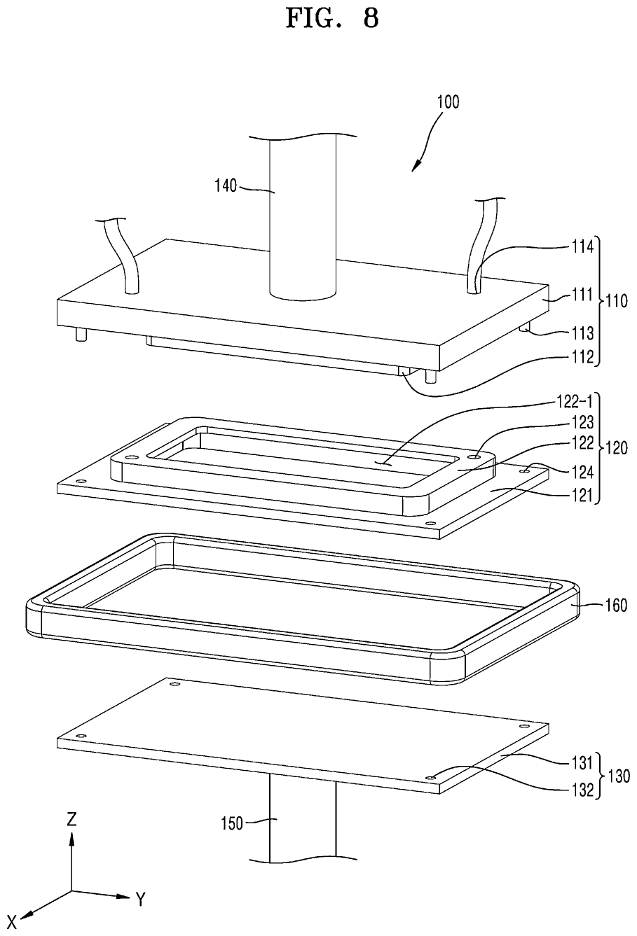

In an embodiment, the touch sensor layer TSL may be formed in the form of a panel or film. Alternatively, the touch sensor layer TSL may be integrally formed with the display panel DP. As an example, in an embodiment in which the touch sensor layer TSL includes a film, the touch sensor layer TSL may be integrally formed with a thin-film encapsulation layer TFE (see FIG. 8) configured to encapsulate the display panel DP. However, embodiments of the present disclosure are not necessarily limited thereto.

For example, in an embodiment, the touch sensor layer TSL may be an electrode in the form of a pattern disposed on the display panel DP. In this embodiment, wirings may be disposed on the thin-film encapsulation layer TFE to cross each other, and a change in a capacitance variable according to a user's touch may be measured at the crossing point of the wirings. The touch sensor layer TSL may be connected to the display circuit board 51.

In an embodiment, the touch sensor driver 53 may be configured to apply touch driving signals to the touch sensor layer TSL, sense first sensing signals sensed by the touch sensor layer TSL, and calculate a user's touch position by analyzing the first sensing signals. In addition, the touch sensor driver 53 may be configured to apply touch driving signals to a sensor, sense second sensing signals sensed by the sensor, and calculate a touch position of a signal input unit by analyzing the second sensing signals.

In an embodiment, a functional layer may be disposed on the touch sensor layer TSL. The functional layer may include an anti-reflection layer. The anti-reflection layer may reduce reflectivity of light (e.g., external light) incident through the display apparatus 1 from the outside (e.g., the external environment).

In an embodiment, the anti-reflection layer may include a polarizing film. In an embodiment, the polarizing film may include a linear polarizing plate and a phase-retarding film such as a λ/4 (quarter-wave) plate. The phase-retarding film may be disposed on the touch sensor layer TSL, and the linear polarizing film may be disposed on the phase-retarding film.

In an embodiment, the anti-reflection layer may include a filter layer including a black matrix and color filters. The color filters may be arranged by taking into account colors of light emitted respectively from the sub-pixels of the display panel DP. As an example, in an embodiment the filter layer may include a red, green, or blue color filter. In this embodiment, the filter layer may be disposed on the touch sensor layer TSL of the display panel DP without a separate adhesive layer.

In an embodiment, the anti-reflection layer may include a destructive interference structure. The destructive interference structure may include a first reflection layer and a second reflection layer respectively disposed on different layers from each other. First-reflected light and second-reflected light respectively reflected by the first reflection layer and the second reflection layer may destructively interfere and thus the reflectivity of external light may be reduced.

In an embodiment, the functional layer may further include an impact absorbing layer. In this embodiment, the impact absorbing layer may protect structures of the display panel and the like thereunder from external impacts. In an embodiment, the impact absorbing layer may be a polymer film. The polymer film may include, for example, at least one of polyethylene terephthalate (PET), polyethylene naphthalate (PEN), polyether sulfone (PES), polyimide (PI), polyarylate (PAR), polycarbonate (PC), polymethyl methacrylate (PMMA), or cycloolefin copolymer (COC).

In an embodiment, the functional layer may include an anti-reflection layer and an impact absorbing layer. In this embodiment, the anti-reflection layer and the impact absorbing layer may be sequentially stacked on the display panel DP or the touch sensor layer TSL.

The display circuit board 51 may be attached on one side of the display panel DP. For example, in an embodiment the display circuit board 51 may be attached to pads prepared on one side of the display panel DP using an isotropic conductive film.

In an embodiment, the display circuit board 51 may be bent from above to below the display panel DP. In some embodiments, the display circuit board 51 may be connected to a main circuit board 70 through a display connector.

The bracket 60 for supporting the display panel DP may be disposed under (e.g., directly thereunder) the display panel DP. The bracket 60 may be arranged to receive the display panel DP. In an embodiment, the bracket 60 may include plastic, metal, or both plastic and metal. In this embodiment, the bracket 60 may include a connector hole 61 through which a connector passes. In addition, the bracket 60 may include a camera hole 62 into which a camera apparatus 73 is inserted.

A receiving space in which a protective layer is received may be disposed in the bracket 60. In addition, the bracket 60 may include a supporter 63 to support the backside of the display panel DP. In an embodiment, the supporter 63 protrudes towards the display panel DP (e.g., in the Z direction). In this embodiment, the supporter 63 may be closely attached to the backside of the display panel DP.

The main circuit board 70 may be provided separately from the display circuit board 51 or may be provided integrally with the display circuit board 51. In an embodiment in which the main circuit board 70 and the display circuit board 51 are separately provided from each other, the main circuit board 70 and the display circuit board 51 may be connected to each other using a cable and the like. Hereinafter, for convenience of description, an embodiment in which the main circuit board 70 and the display circuit board 51 are separately provided is mainly described in detail.

In an embodiment, the main circuit board 70 may include a main processor 71, the camera apparatus 73, a main connector 75, and components. The main processor 71 may include an integrated circuit. In an embodiment, the camera apparatus 73 may be disposed on both the upper surface and the lower surface of the main circuit board 70, and the main processor 71 and the main connector 75 may each be disposed on one of the upper surface and the lower surface of the main circuit board 70.

The main processor 71 may be configured to control all functions of the display apparatus 1. As an example, in an embodiment the main processor 71 may be configured to output digital video data to the display driver 52 through the display circuit board 51 such that the display panel DP displays images. In addition, the main processor 71 may be configured to receive sensed data from the touch sensor driver 53. The main processor 71 may determine whether a user directly touches the touchscreen according to sensed data, and execute an operation corresponding to a user's direct touch or proximity touch. As an example, in an embodiment the main processor 71 may analyze sensed data and calculate a user's touch coordinates. The main processor 71 may then execute an application indicated by an icon the user touches, or perform an operation. The main processor 71 may be an application processor including an integrated circuit, a central processing unit, or a system chip.

The camera apparatus 73 may process image frames such as at least one still image and/or moving image obtained by an image sensor in a camera mode, and output the image frames to the main processor 71. The camera apparatus 73 may include at least one of a camera sensor (e.g., a charge-coupled device (CCD), a complementary metal oxide semiconductor (CMOS), and the like), a photo sensor (e.g., an image sensor), and a laser sensor. The camera apparatus 73 may be connected to an image sensor among the components overlapping a component area and may process images input to the image sensor.

In an embodiment, a cable passing through the cable hole 61 of the bracket 60 may be connected to the main connector 75, and thus, the main circuit board 70 may be electrically connected to the display circuit board 51.

In an embodiment, the main circuit board 70 may further include at least one of wireless communication units, at least one of input units, at least one of sensors, at least one of output units, at least one of interfaces, a memory, and a power supply unit in addition to the main processor 71, the camera apparatus 73, and the main connector 75.

The wireless communication unit may include at least one of a broadcasting receiving module, a mobile communication module, a wireless Internet module, a short distance communication module, and a position information module.

The broadcasting receiving module may be configured to receive broadcasting signals and/or broadcasting-related information from an external broadcasting management server through a broadcasting channel. The broadcasting channel may include satellite channels and/or groundwave channels.

The mobile communication module may be configured to transmit/receive radio signals to/from at least one of a base station, an external terminal, and a server on a mobile communication network established according to technology standards for mobile communication or communication schemes (e.g., Global System for Mobile communication (GSM), Code Division Multi Access (CDMA), Code Division Multi Access 2000 (CDMA2000), Enhanced Voice-Data Optimized or Enhanced Voice-Data Only (EV-DO), Wideband CDMA (WCDMA), High Speed Downlink Packet Access (HSDPA), High Speed Uplink Packet Access (HSUPA), Long Term Evolution (LTE), Long Term Evolution-Advanced (LTE-A), and the like). Wireless signals may include voice call signals, image communication call signals, or various types of data corresponding to text/multimedia message transmission/reception.

The wireless Internet module may denote a module for wireless Internet access. The wireless Internet module may be configured to transmit/receive radio signals on a communication network according to wireless Internet technologies. Examples of wireless Internet technologies include wireless local area network (WLAN), wireless-fidelity (Wi-Fi), Wi-Fi Direct, and digital living network alliance (DLNA).

The short distance communication module is for short range communication, and may support short distance communication by using at least one of Bluetooth™, Radio Frequency Identification (RFID), Infrared Data Association; IrDA (IrDA), Ultra Wideband (UWB), ZigBee, Near Field Communication (NFC), Wi-Fi, Wi-Fi Direct, and Wireless Universal Serial Bus (Wireless USB) technologies. The short distance communication module may be configured to support wireless communication between the display apparatus 1 and a wireless communication system, between the display apparatus 1 and another the electronic apparatus, or between the display apparatus 1 and a network in which another the electronic apparatus (e.g., an external server) is located, through a short distance wireless area network. The short distance wireless area network may be a wireless personal area network. In an embodiment, the other electronic apparatus may be a wearable device that may exchange data, or operate with the display apparatus 1.

The position information module is a module for obtaining the position (e.g., a current position) of the display apparatus 1. Representative examples of the position information module 525 include a Global Positioning System (GPS) module or a Wi-Fi module. As an example, in an embodiment in which the GPS module is utilized, the display apparatus 1 may obtain the position of the display apparatus 1 by using signals sent by GPS satellites. In addition, the display apparatus 1 may obtain the position of the display apparatus 1 based on information of a wireless access point (AP) that transmits/receives radio signals to/from the Wi-Fi module by using the Wi-Fi module. While the position information module may be a module for obtaining the position (e.g., a current position) of the display apparatus 1, the position information module is not necessarily limited to a module for directly calculating or obtaining the position of the display apparatus 1.

The input unit may include an image input unit such as the camera apparatus for inputting image signals, a sound input unit such as a microphone for inputting sound signals, and the input unit for receiving information from a user.

The camera apparatus 73 processes image frames such as still images or moving images obtained by an image sensor in an image communication mode or a photographing mode. The processed image frames may be displayed on the display panel DP or stored in the memory.

The microphone processes external sound signals as electrical voice data. The processed voice data may be variously utilized according to a function (e.g., an application in execution) being performed in the display apparatus 1. Various noise cancelling algorithms may be implemented in the microphone. The various noise cancelling algorithms may cancel noises occurring during a process of receiving external sound signals.

The main processor 71 may be configured to control an operation of the display apparatus 1 to correspond to information input through the input unit. In an embodiment, the input unit may include a mechanical input means such as buttons, a dome switch, a jog wheel, a jog switch, and the like, or a touch input means located on the lower surface or the lateral surface of the display apparatus 1. The touch input means may include the touch sensor layer of the display panel DP.

The sensor may include at least one sensor that senses at least one of information inside the display apparatus 1, peripheral environmental information surrounding the display apparatus 1, and user information, and generates sensing signals corresponding thereto. The main processor may control driving or an operation of the display apparatus 1 based on the sensing signals, or perform data processing, a function, or an operation related to an application installed in the display apparatus 1. In an embodiment, the sensor may include at least one of a proximity sensor, an illumination sensor, an acceleration sensor, a magnetic sensor, a G-sensor, a gyroscope sensor, a motion sensor, an RGB sensor, an infrared sensor, a finger scan sensor, an ultrasonic sensor, an optical sensor, a battery gauge, an environment sensor (e.g., a barometer, a hygrometer, a thermometer, a radiation detection sensor, a heat detection sensor, a gas detection sensor, and the like), a chemical sensor (e.g., an electronic nose, a healthcare sensor, a biometric sensor, and the like), etc.

A proximity sensor denotes a sensor that detects whether there is an object approaching (e.g., in proximity to) a preset detection surface or an object existing in the neighborhood by using electromagnetic force, an infrared ray, or the like without a mechanical contact. Examples of the proximity sensor include a transmissive photo-electric sensor, a direct reflective photo-electric sensor, a mirror reflective photo-electric sensor, a high-frequency oscillation type proximity sensor, a capacitance type proximity sensor, a magnetic proximity sensor, and an infrared proximity sensor. The proximity sensor may sense not only a proximity touch, but also a proximity touch pattern such as a proximity touch distance, a proximity touch direction, a proximity touch velocity, a proximity touch time, a proximity touch position, and a proximity touch movement state. The main processor may process data (e.g., information) corresponding to a proximity touch operation and a proximity touch pattern sensed by the proximity sensor, and control the display panel DP to display visual information corresponding to the processed data.

The ultrasonic sensor may recognize the position information of an object by using ultrasonic waves. The main processor may calculate the position of an object by using information sensed by an optical sensor and a plurality of ultrasonic sensors. Since the velocity of light is different from the velocity of ultrasonic waves, the position of an object may be calculated by using a time during which light reaches a light sensor and a time during which ultrasonic waves reach the ultrasonic sensor.

The output unit generates output related to vision, hearing, or tactile sensation and may include at least one of a sound output unit, a haptic module, and a light output unit. However, embodiments of the present disclosure are not necessarily limited thereto.

In an embodiment, the sound output unit may be configured to output sound data received by the wireless communication unit or stored in the memory in a call reception mode, a communication mode or recoding mode, a voice recognition mode, a broadcasting reception mode, and the like. The sound output unit may output sound signals related to a function (e.g., a call signal reception tone, a message reception tone, and the like) performed by the display apparatus 1. The sound output unit may include a receiver and a speaker. At least one of the receiver and the speaker may be a sound generator that is attached under the display panel DP and vibrates the display panel DP to output sounds. In an embodiment, the sound generator may be a piezoelectric element or a piezoelectric actuator that contracts and expands according to electrical signals, or an exciter that generates magnetic force by using a voice coil to vibrate the display panel DP.

The haptic module is configured to generate various haptic effects that may be felt by a user. For example, the haptic module may provide vibrations as a haptic effect to a user. The intensity, the pattern, and the like of vibrations generated by the haptic module may be controlled by a user's selection or setting of the main processor. As an example, the haptic module may be configured to synthesize different vibrations to output the same vibration, or sequentially output the different vibrations. The haptic module may be configured to generate various tactile effects such as effects due to the arrangement of pins that move perpendicular to the surface of a skin in direct contact, the blowing force or suction power of air through a nozzle or a suction port, sweep to the skin surface, an electrode contact, stimulus of electrostatic force, and effects due to reproduction of cool and warm feeling using elements that may absorb heat or generate heat, as well as vibrations. The haptic module may be configured to not only transfer a tactile effect through a direct contact but also implement a tactile effect such that a user may feel the tactile effect through a muscle sense in fingers or arms.

The light output unit is configured to output signals for notifying the user of an occurrence of an event by using light of a light source. Examples of an event generated in the display apparatus 1 may include message reception, call signal reception, a missed call, alarm, schedule notification, e-mail reception, information reception through an application, and the like. Signals output by the light output unit are implemented when the display apparatus 1 emits light of a single color or a plurality of colors to the front surface or the rear surface. The signal output may end when the display apparatus 1 detects that a user confirms an event.

The interface serves as a path with various kinds of external apparatuses connected to the display apparatus 1. In an embodiment, the interface may include at least one of a wired/wireless headset port, an external charger port, a wired/wireless data port, a memory card part, a port for connecting an apparatus having an identification module, an audio input/output (I/O) port, a video I/O port, and an earphone port. When an external apparatus is connected to the interface, the display apparatus 1 may perform an appropriate control related to the external apparatus connected.

The memory stores data that support various functions of the display apparatus 1. The memory may store a plurality of application programs driven in the display apparatus 1, data for operations of the display apparatus 1, and commands. At least some of the plurality of application programs may be downloaded from an external server through wireless communication. The memory may be configured to store an application program for operations of the main processor and temporarily store data input/output, for example, data such as a phone book, messages, still images, moving images, and the like. In addition, the memory may be configured to store haptic data for various patterns of vibrations provided to the haptic module and various sound data regarding various sounds provided to the sound output unit. In an embodiment, the memory may include at least one type of storing medium among a flash memory type, a hard disk type, a solid state disk (SSD) type, a silicon disk drive (SDD) type, a multimedia card micro type, a card type memory (e.g., secure digital (SD) or extreme digital (XD) memory), a random access memory (RAM), a static random access memory (SRAM), a read-only memory (ROM), an electrically erasable programmable read-only memory (EEPROM), a programmable read-only memory (PROM), a magnetic memory, a magnetic disk, and an optical disk.

The power supply unit may be configured to receive an external power and an internal power under control of the main processor, and supply power to respective elements included in the display apparatus 1. The power supply unit may include a battery. In addition, the power supply unit includes a connection port. The connection port may be configured as an example of the interface to which an external charger is electrically connected. The external charger supplies power to charge the battery. Alternatively, the power supply unit may be configured to charge the battery wirelessly without using the connection port. The battery may receive power from an external wireless power transfer apparatus by using at least one of inductive coupling and magnetic resonance coupling. The inductive coupling is based on magnetic induction, and the magnetic resonance coupling is based on electromagnetic resonance. The battery may be arranged not to overlap the main circuit board in a third direction (e.g., the z direction). The battery may overlap a battery hole of the bracket 60.

The lower cover 90 may be disposed under (e.g., disposed directly thereunder) the main circuit board 70 and the battery. The lower cover 90 may be coupled and fixed to the bracket 60. The lower cover 90 may form the lower appearance of the display apparatus 1. In an embodiment, the lower cover 90 may include plastic, metal, or both plastic and metal.

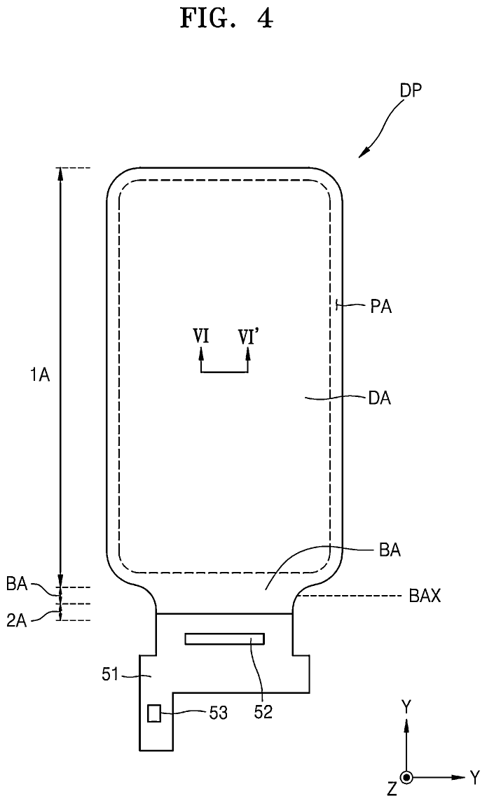

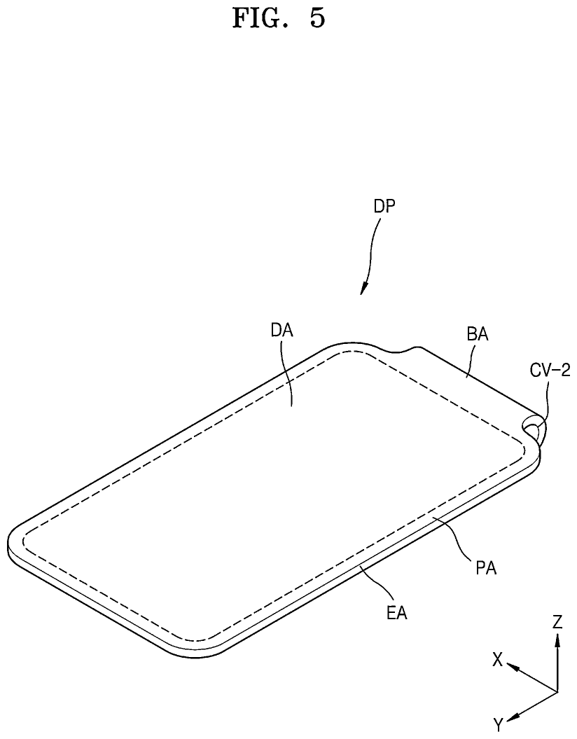

FIG. 4 is a schematic plan view of the display panel shown in FIG. 2. FIG. 5 is a schematic perspective view of a bent form of at least a portion of the display panel shown in FIG. 4.

Referring to FIGS. 4 and 5, the display panel DP may be a light-emitting display panel including a light-emitting element. As an example, in an embodiment the display panel DP may be an organic light-emitting display panel that uses an organic light-emitting diode that includes an organic emission layer, an ultra-miniature light-emitting diode display panel that uses a micro light-emitting diode, a quantum-dot light-emitting display panel that uses a quantum-dot light-emitting diode including a quantum-dot emission layer, or an inorganic light-emitting display panel that uses an inorganic light-emitting element including an inorganic semiconductor.

The display panel DP may be a flexible display panel which has flexibility and thus is easily bendable, foldable, or rollable. As an example, the display panel DP may include a foldable display panel that is foldable and unfoldable, a curved display panel that has a curved display surface, a bended display panel in which a region except a display surface is bent (e.g., in a bent state), a rollable display panel that is rollable and unrollable, and a stretchable display panel that is stretchable.

The display panel DP may be a transparent display panel such that an object or background disposed below the display panel DP is viewable from the upper surface of the display panel DP. Alternatively, the display panel DP may be a reflective display panel that may reflect an object or background over the upper surface of the display panel DP.

The display panel DP may include a display area DA and a peripheral area PA arranged to surround the display area DA (e.g., in the X and/or Y directions). Images are displayed in the display area DA. A separate driving circuit, a pad, and the like may be arranged in the peripheral area PA.

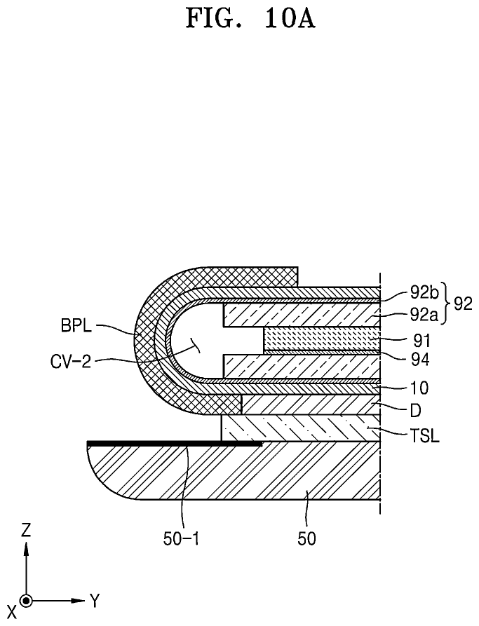

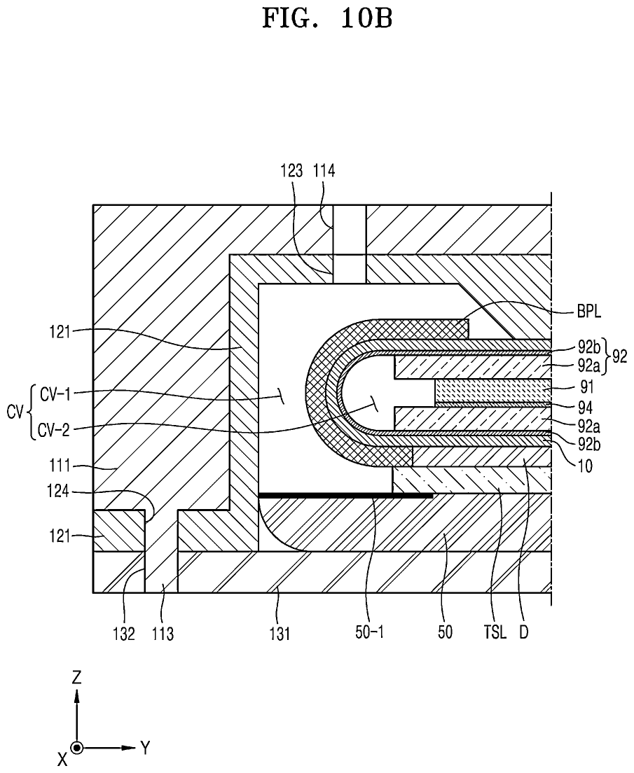

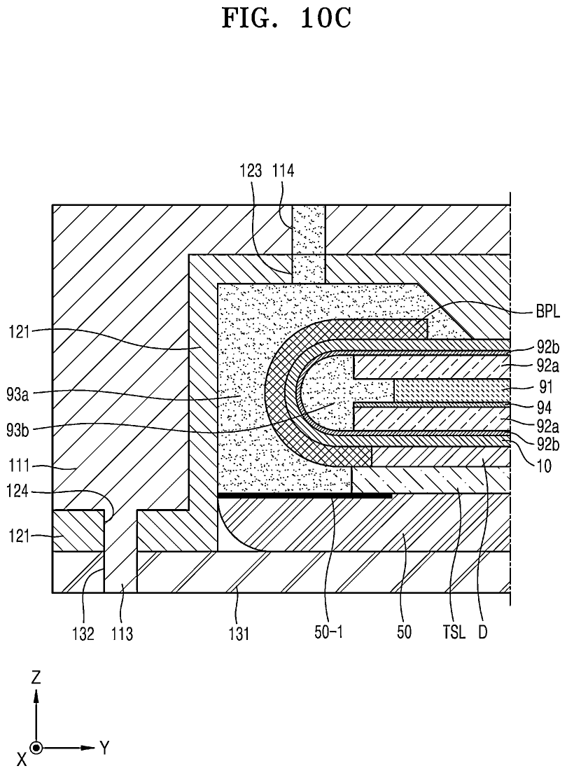

In addition, the display panel DP may include the first area 1A, the bent area BA, and the second area 2A. The first area 1A is arranged in the display area DA, the bent area BA may be bent around a bending axis BAX, and the second area 2A is connected to the bent area BA and connected to the display circuit board 51. For example, the bent area BA may connect (e.g., directly connect) the first area 1A and the second area 2A to each other. In an embodiment, the second area 2A and the bent area BA may be included in the peripheral area PA, and images may be displayed in the second area 2A and the bent area BA. In an embodiment, in the display panel DP, a portion of the substrate 10 may be bent around the virtual bending axis BAX arranged in the bent area BA. In this embodiment, the first area 1A, the second area 2A, and the bent area BA may form a ‘U’ shape to form a second space CV-2 in which the second protective layer 93b is arranged. In an embodiment, the first protective layer 93a may be arranged in the outer surface of an edge EA and the bent area BA of the display panel DP, and the first protective layer may be arranged in a first space CV-1 (FIG. 10B).

The display circuit board 51 may be attached the edge on one side of the display panel DP. For example, in an embodiment the display circuit board 51 may be attached to a lower edge (e.g., in the Y direction) of the display panel DP. However, embodiments of the present disclosure are not necessarily limited thereto. In an embodiment, one side of the display circuit board 51 may be attached to the edge of one side of the display panel DP by using an anisotropic conductive film.

In an embodiment, the display driver 52 may be disposed on the display circuit board 51. The display driver 52 may receive control signals and power voltages, generate and output signals and voltages for driving the display panel DP. The display driver 52 may include an integrated circuit (IC).

The display circuit board 51 may be attached to the display panel DP. In an embodiment, the display circuit board 51 and the display panel DP may be attached to each other using an isotropic conductive film. The display circuit board 51 may be a flexible printed circuit board (FPCB) that may be bent, or a composite printed circuit board including both a rigid printed circuit board (PCB) that is rigid and not easily bent and a flexible printed circuit board.

In an embodiment, the touch sensor driver 53 may be disposed on the display circuit board 51. The touch sensor driver 53 may include an integrated circuit. The touch sensor driver 53 may be attached to the display circuit board 51. The touch sensor driver 53 may be electrically connected to touch electrodes of a touch sensor layer of the display panel DP through the display circuit board 51.

The touch sensor layer of the display panel DP may sense a user's touch input by using at least one of various touch methods such as a resistance layer method, a capacitance method and the like. As an example, in an embodiment in which the touch sensor layer of the display panel DP senses a user's touch input by using a capacitance method, the touch sensor driver 53 may determine whether a user touches the touchscreen layer by applying driving signals to driving electrodes among touch electrodes, and sensing voltages charged in a mutual capacitance between the driving electrodes and the sensing electrodes through the sensing electrodes among the touch electrodes. A user's touch may include a contact touch and a proximity touch. A contact touch denotes that an object, such as a user's finger or a pen, is in direct contact with the cover member disposed on the touch sensor layer. A proximity touch, such as hovering, denotes that an object, such as a user's finger or a pen, is located near the cover member, away from the cover member. The touch sensor driver 53 may be configured to transfer sensor data to the main processor according to sensed voltages, and the main processor may be configured to calculate touch coordinates at which a touch input occurs by analyzing the sensor data.

A power supply unit may be additionally disposed on the display circuit board 51. The power supply unit is configured to supply driving voltages for driving the pixels of the display panel DP, the scan driver, and the display driver 52. Alternatively, the power supply unit may be integrated with the display driver 52. In this embodiment, the display driver 52 and the power supply unit may be implemented in one integrated circuit.

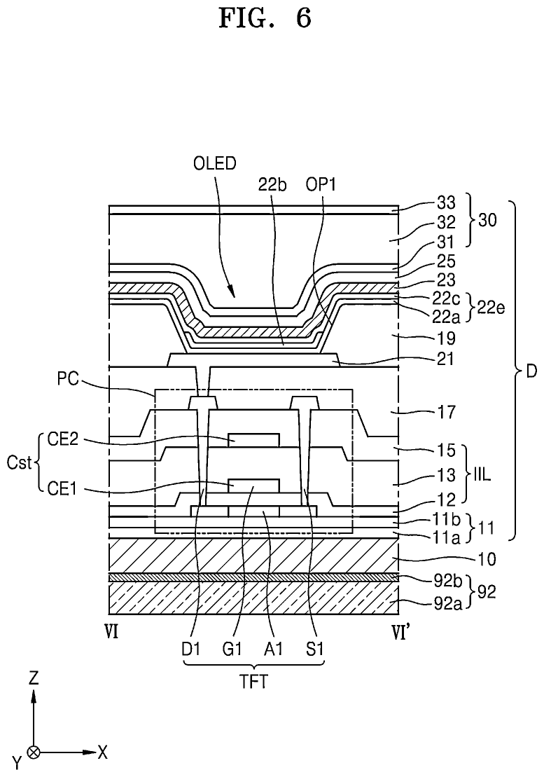

FIG. 6 is a cross-sectional view of the display panel DP, taken along line VI-VI′ of FIG. 4.

Referring to FIG. 6, the display panel DP may include the substrate 10 and the display layer D. In an embodiment, the display layer D may include a buffer layer 11, a circuit layer, a display element layer, and a thin-film encapsulation layer 30.

As described above, the substrate 10 may include an insulating material such as glass, quartz, a polymer resin or the like. The substrate 10 may be a flexible substrate that is bendable, foldable, and rollable.

The buffer layer 11 may be disposed on the substrate 10 (e.g., disposed directly thereon in the Z direction). The buffer layer 11 may reduce or block penetration of foreign materials, moisture, or external air from below the substrate 10, and provide a flat surface on the substrate 10. In an embodiment, the buffer layer 11 may include an inorganic material, an organic material, or an organic/inorganic composite material, and include a single layer or a multi-layer including an inorganic material and an organic material, the inorganic material including oxide or nitride. In an embodiment, a barrier layer may be further arranged between the substrate 10 and the buffer layer 11, the barrier layer blocking penetration of external air. In an embodiment, the buffer layer 11 may include silicon oxide (SiO₂) or silicon nitride (SiNₓ). In an embodiment, the buffer layer 11 may include a first buffer layer 11a and a second buffer layer 11b that are stacked (e.g., in the Z direction).

In an embodiment, the circuit layer may be disposed on the buffer layer 11 and may include a pixel circuit PC, a first gate insulating layer 12, a second gate insulating layer 13, an interlayer insulating layer 15, and a planarization layer 17. The pixel circuit PC may include a thin-film transistor TFT and a storage capacitor Cst.

The thin-film transistor TFT may be disposed on the buffer layer 11 (e.g., disposed directly thereon in the Z direction). The thin-film transistor TFT may include a first semiconductor layer A1, a first gate electrode G1, a first source electrode S1, and a first drain electrode D1. The thin-film transistor TFT may be connected to (e.g., electrically connected thereto) an organic light-emitting diode OLED to drive the organic light-emitting diode OLED.

In an embodiment, the first semiconductor layer A1 may be disposed on (e.g., disposed directly thereon in the Z direction) the buffer layer 11 and may include polycrystalline silicon. However, embodiments of the present disclosure are not necessarily limited thereto. For example, in an embodiment, the first semiconductor layer A1 may include amorphous silicon. In an embodiment, the first semiconductor layer A1 may include an oxide of at least one of indium (In), gallium (Ga), stannum (Sn), zirconium (Zr), vanadium (V), hafnium (Hf), cadmium (Cd), germanium (Ge), chromium (Cr), titanium (Ti), and zinc (Zn). The first semiconductor layer A1 may include a channel region, a source region, and a drain region, the source region and the drain region being doped with impurities.

The first gate insulating layer 12 may be disposed to cover the first semiconductor layer A1. In an embodiment, the first gate insulating layer 12 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The first gate insulating layer 12 may include a single layer or a multi-layer including the inorganic insulating material.

The first gate electrode G1 is disposed on (e.g., disposed directly thereon) the first gate insulating layer 12 to overlap the first semiconductor layer A1 (e.g., in the Z direction). In an embodiment, the first gate electrode G1 may include at least one of molybdenum (Mo), aluminum (Al), copper (Cu), titanium (Ti) and the like and include a single layer or a multi-layer. As an example, the first gate electrode G1 may include a single Mo layer.

The second gate insulating layer 13 may cover the first gate electrode G1. In an embodiment, the second gate insulating layer 13 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The second gate insulating layer 13 may include a single layer or a multi-layer including the inorganic insulating material.

A first upper electrode CE2 of the storage capacitor Cst may be disposed on the second gate insulating layer 13 (e.g., disposed directly thereon in the Z direction).

The first upper electrode CE2 may overlap (e.g., in the Z direction) the first gate electrode G1 therebelow in the first display area DA1. The first gate electrode G1 and the first upper electrode CE2 overlapping each other with the second gate insulating layer 13 therebetween may constitute the storage capacitor Cst. The first gate electrode G1 may serve as a first lower electrode CE1 of the storage capacitor Cst.

In an embodiment, the first upper electrode CE2 may include aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and/or copper (Cu), and include a single layer or a multi-layer including the above materials.

The interlayer insulating layer 15 may be formed to cover the first upper electrode CE2. In an embodiment, the interlayer insulating layer 15 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The interlayer insulating layer 15 may include a single layer or a multi-layer including the inorganic insulating material.

The first source electrode S1 and the first drain electrode D1 are disposed on the interlayer insulating layer 15 (e.g., disposed directly thereon in the Z direction). In an embodiment, the first source electrode S1 and the first drain electrode D1 may each include a conductive material including molybdenum (Mo), aluminum (Al), copper (Cu), and titanium (Ti) and include a single layer or a multi-layer including the above materials. As an example, the source electrode SE and the drain electrode DE may have a multi-layered structure of Ti/Al/Ti.

The planarization layer 17 may be disposed to cover the first source electrode S1 and the first drain electrode D1. The planarization layer 17 may have a flat upper surface such that a pixel electrode 21 disposed thereon is formed flat.

The planarization layer 17 may include an organic material or an inorganic material, and include a single-layered structure or a multi-layered structure. For example, in an embodiment the planarization layer 17 may include a general-purpose polymer such as benzocyclobutene (BCB), polyimide, hexamethyldisiloxane (HMDSO), polymethylmethacrylate (PMMA) or polystyrene, polymer derivatives having a phenol-based group, an acryl-based polymer, an imide-based polymer, an aryl ether-based polymer, an amide-based polymer, a fluorine-based polymer, a p-xylene-based polymer, or a vinyl alcohol-based polymer. The planarization layer 17 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). In an embodiment, while the planarization layer 17 is formed, to provide a flat upper surface after the initial layer is formed, chemical mechanical polishing may be performed on the upper surface of the layer forming the planarization layer 17.

In an embodiment, the planarization layer 17 may have a via hole that exposes one of the first source electrode S1 and the first drain electrode D1 of the thin-film transistor TFT. The pixel electrode 21 may be electrically connected to the thin-film transistor TFT by being in direct contact with the first source electrode S1 or the first drain electrode D1 through the via hole.

In an embodiment, the pixel electrode 21 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). The pixel electrode 21 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. As an example, in an embodiment the pixel electrode 21 may have a structure including layers on/under the reflective layer and the layers may include ITO, IZO, ZnO, or In₂O₃. In this embodiment, the pixel electrode 21 may have a stack structure of ITO/Ag/ITO.

In an embodiment, a pixel-defining layer 19 may cover the edges of the pixel electrode 21 on the planarization layer 17 and may have a first opening OP1 that exposes the central portion of the pixel electrode 21. An emission area of the organic light-emitting diode OLED, such as the size and shape of the sub-pixel P are defined by the first opening OP1.

The pixel-defining layer 19 may prevent arcs and the like from occurring at the edges of the pixel electrode 21 by increasing a distance between the edges of the pixel electrode 21 and an opposite electrode 23 over the pixel electrode 21. In an embodiment, the pixel-defining layer 19 may include an organic insulating material such as polyamide, an acryl resin, benzocyclobutene, and hexamethyldisiloxane (HMDSO), and be formed by spin coating and the like.

An emission layer 22b is disposed in the first opening OP1 of the pixel-defining layer 19. The emission layer 22b is formed to correspond to the pixel electrode 21. In an embodiment, the emission layer 22b may include a polymer material or a low-molecular weight material and be configured to emit red, green, blue, or white light. However, embodiments of the present disclosure are not necessarily limited thereto.

In an embodiment, an organic functional layer 22e may be disposed on and/or under the emission layer 22b. The organic functional layer 22e may include a first functional layer 22a and/or a second functional layer 22c. However, the first functional layer 22a and/or the second functional layer 22c may be omitted.

The first functional layer 22a may be disposed under the emission layer 22b. In an embodiment, the first functional layer 22a may include a single layer or a multi-layer including an organic material. The first functional layer 22a may be a hole transport layer (HTL) having a single-layered structure. Alternatively, the first functional layer 22a may include a hole injection layer (HIL) and an HTL. The first functional layer 22a may be integrally formed to correspond to the organic light-emitting diodes OLED included in the display area DA.

The second functional layer 22c may be disposed on the emission layer 22b. In an embodiment, the second functional layer 22c may include a single layer or a multi-layer including an organic material. The second functional layer 22c may include an electron transport layer (ETL) and/or an electron injection layer (EIL). The second functional layer 22c may be integrally formed to correspond to the organic light-emitting diodes OLED included in the display area DA.

The opposite electrode 23 may be disposed on the second functional layer 22c. The opposite electrode 23 may include a conductive material having a low work function. As an example, in an embodiment the opposite electrode 23 may include a (semi) transparent layer including silver (Ag), magnesium (Mg), aluminum (Al), platinum (Pt), palladium (Pd), gold (Au), nickel (Ni), neodymium (Nd), iridium (Ir), chrome (Cr), or an alloy thereof. Alternatively, the opposite electrode 23 may further include a layer on the (semi) transparent layer, the layer including ITO, IZO, ZnO, or In₂O₃. The opposite electrode 23 may be integrally formed to correspond to the organic light-emitting diodes OLED included in the display area DA.

Layers from the pixel electrode 21 to the opposite electrode 23 formed in the display area DA may constitute the organic light-emitting diode OLED.

An upper layer 25 including an organic material may be formed on the opposite electrode 23. The upper layer 25 may be a layer for protecting the opposite electrode 23 and simultaneously increasing a light-extracting efficiency. The upper layer 25 may include an organic material having a higher refractive index than that of the opposite electrode 23. Alternatively, the upper layer 25 may include layers of different refractive indexes that are stacked (e.g., in the Z direction). As an example, in an embodiment the upper layer 25 may include a high refractive index layer/a low refractive index layer/a high refractive index layer that are stacked (e.g., in the Z direction). In this embodiment, the refractive index of the high refractive index layer may be greater than or equal to about 1.7, and the refractive index of the low refractive index layer may be less than or equal to about 1.3.

In an embodiment, the upper layer 25 may additionally include lithium fluoride (LiF). Alternatively, the upper layer 25 may additionally include an inorganic insulating material such as silicon oxide (SiO₂) and silicon nitride (SiNₓ). However, embodiments of the present disclosure are not necessarily limited thereto and the upper layer 25 may be omitted when needed. However, an embodiment in which the upper layer 25 is disposed on the opposite electrode 23 is mainly described in detail.

In an embodiment, the display apparatus DP may include the thin-film encapsulation layer 30 shielding the upper layer 25.

In an embodiment, the thin-film encapsulation layer 30 may be disposed to be in direct contact with the opposite electrode 23 or the upper layer 25. In this embodiment, the thin-film encapsulation layer 30 may cover the display area DA and a portion of the peripheral area PA to prevent penetration of external moisture and oxygen. The thin-film encapsulation layer 30 may include at least one inorganic encapsulation layer and at least one organic encapsulation layer. Hereinafter, for convenience of description, an embodiment in which the thin-film encapsulation layer 30 includes a first inorganic encapsulation layer 31, an organic encapsulation layer 32, and a second inorganic encapsulation layer 33 that are sequentially stacked on the upper surface of the upper layer 25 (e.g., in the Z direction) is mainly described in detail.

In this embodiment, the first inorganic encapsulation layer 31 may cover the upper layer 25 and may include silicon oxide, silicon nitride, and/or silicon oxynitride. Since the first inorganic encapsulation layer 31 is formed along a structure thereunder, the upper surface of the first inorganic encapsulation layer 31 is not flat. The organic encapsulation layer 32 may cover the first inorganic encapsulation layer 31 and, unlike the first inorganic encapsulation layer 31, the upper surface of the organic encapsulation layer 32 may be approximately flat. For example, the upper surface of a portion of the organic encapsulation layer 32 that corresponds to the display area DA may be approximately flat. In an embodiment, the organic encapsulation layer 32 may include at least one material among polyethylene terephthalate, polyethylene naphthalate, polycarbonate, polyimide, polyethylene sulfonate, polyoxymethylene, and polyarylate, hexamethyldisiloxane. The second inorganic encapsulation layer 33 may cover the organic encapsulation layer 32 and may include silicon oxide, silicon nitride, and/or silicon oxynitride.

The touch sensor layer may be disposed on the thin-film encapsulation layer 30 (e.g., in the Z direction).

The protective film 92 including the protective film base 92a and the adhesive layer 92b may be disposed on the lower surface of the substrate 10.

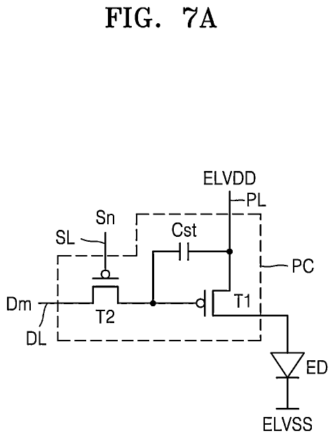

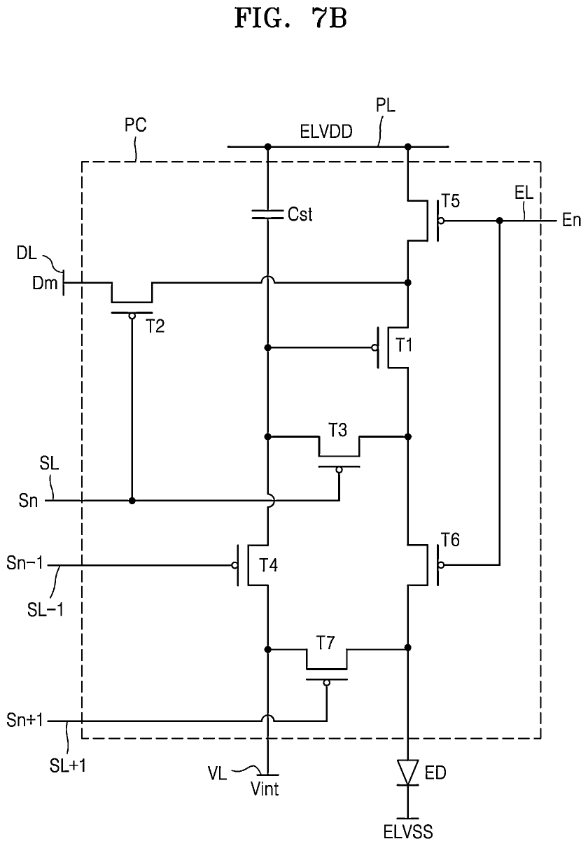

FIGS. 7A and 7B are circuit diagrams of a circuit of the display panel DP shown in FIG. 6.

Referring to FIGS. 7A and 7B, the pixel circuit PC may be connected to a light-emitting element ED to implement light emission of sub-pixels. In an embodiment, the pixel circuit PC includes a driving thin-film transistor T1, a switching thin-film transistor T2, and a storage capacitor Cst. The switching thin-film transistor T2 is connected to a scan line SL and a data line DL, and configured to transfer a data signal Dm to the driving thin-film transistor T1 according to a scan signal Sn. The data signal Dm is input through the data line DL, and the scan signal Sn is input through the scan line SL.

The storage capacitor Cst may be connected to the switching thin-film transistor T2 and a driving voltage line PL and configured to store a voltage corresponding to a difference between a voltage transferred from the switching thin-film transistor T2 and a driving voltage ELVDD supplied to the driving voltage line PL.

The driving thin-film transistor T1 may be connected to the driving voltage line PL and the storage capacitor Cst and configured to control a driving current according to the voltage stored in the storage capacitor Cst. The driving current flows from the driving voltage line PL to the light-emitting element ED. The light-emitting element ED may be configured to emit light having a preset brightness corresponding to the driving current.

Although it is described with reference to FIG. 7A that the pixel circuit PC includes two thin-film transistors and one storage capacitor, embodiments of the present disclosure are not necessarily limited thereto.

Referring to FIG. 7B, in an embodiment the pixel circuit PC may include the driving thin-film transistor T1, the switching thin-film transistor T2, a compensation thin-film transistor T3, a first initialization thin-film transistor T4, an operation control thin-film transistor T5, an emission control thin-film transistor T6, and a second initialization thin-film transistor T7.

Although FIG. 7B shows an embodiment in which each pixel circuit PC includes signal lines SL, SL−1, SL+1, EL, and DL, an initialization voltage line VL, and the driving voltage line PL, embodiments of the present disclosure are not necessarily limited thereto. For example, in an embodiment, at least one of the signal lines SL, SL−1, SL+1, EL, and DL, and/or the initialization voltage line VL may be shared by adjacent pixel circuits.

A drain electrode of the driving thin-film transistor T1 may be electrically connected to the light-emitting element ED through the emission control thin-film transistor T6. In an embodiment, the driving thin-film transistor T1 may be configured to receive a data signal Dm and supply the driving current to the light-emitting element ED according to a switching operation of the switching thin-film transistor T2.

A gate electrode of the switching thin-film transistor T2 is connected to the scan line SL, and a source electrode is connected to the data line DL. A drain electrode of the switching thin-film transistor T2 may be connected to the source electrode of the driving thin-film transistor T1, and connected to the driving voltage line PL through the operation control thin-film transistor T5.

In an embodiment, the switching thin-film transistor T2 is turned on according to a scan signal Sn transferred through the scan line SL and performs a switching operation of transferring a data signal Dm to a source electrode of the driving thin-film transistor T1. The data signal Dm is transferred to the data line DL.

A gate electrode of the compensation thin-film transistor T3 may be connected to the scan line SL. A source electrode of the compensation thin-film transistor T3 is connected to a drain electrode of the driving thin-film transistor T1 and connected to a pixel electrode of the light-emitting element ED through the emission control thin-film transistor T6. A drain electrode of the compensation thin-film transistor T3 may be connected to one of electrodes of the storage capacitor Cst, a source electrode of the first initialization thin-film transistor T4, and a gate electrode of the driving thin-film transistor T1 together. In an embodiment, the compensation thin-film transistor T3 is turned on according to a scan signal Sn received through the scan line SL and diode-connect the driving thin-film transistor T1 by connecting the gate electrode and the drain electrode of the driving thin-film transistor T1 to each other.

A gate electrode of the first initialization transistor T4 may be connected to a previous scan line SL−1. A drain electrode of the first initialization transistor T4 may be connected to the initialization voltage line VL. A source electrode of the first initialization thin-film transistor T4 may be connected to one of the electrodes of the storage capacitor Cst, a drain electrode of the compensation thin-film transistor T3, and a gate electrode of the driving thin-film transistor T1 together. For example, in an embodiment the first initialization thin-film transistor T4 may be turned on according to a previous scan signal Sn−1 received through the previous scan line SL−1 and may perform an initialization operation of initializing the voltage of the gate electrode of the driving thin-film transistor T1 by transferring an initialization voltage Vint to the gate electrode of the driving thin-film transistor T1.

A gate electrode of the operation control thin-film transistor T5 may be connected to the emission control line EL. A source electrode of the operation control thin-film transistor T5 may be connected to the driving voltage line PL. A drain electrode of the operation control thin-film transistor T5 is connected to the source electrode of the driving thin-film transistor T1 and the drain electrode of the switching thin-film transistor T2.

A gate electrode of the emission control thin-film transistor T6 may be connected to the emission control line EL. A source electrode of the emission control thin-film transistor T6 may be connected to the drain electrode of the driving thin-film transistor T1 and the source electrode of the compensation thin-film transistor T3. A drain electrode of the emission control thin-film transistor T6 may be electrically connected to the pixel electrode of the light-emitting element ED. In an embodiment, the operation control thin-film transistor T5 and the emission control thin-film transistor T6 may be simultaneously turned on according to an emission control signal En transferred through the emission control line EL, the driving voltage ELVDD is transferred to the light-emitting element ED, and the driving current flows through the light-emitting element ED.

A gate electrode of the second initialization thin-film transistor T7 may be connected to the next scan line SL+1. A source electrode of the second initialization thin-film transistor T7 may be connected to the pixel electrode of the light-emitting element ED. A drain electrode of the second initialization transistor T7 may be connected to the initialization voltage line VL. In an embodiment, the second initialization thin-film transistor T7 may be turned on according to a next scan signal Sn+1 transferred through the next scan line SL+1 to initialize the pixel electrode of the light-emitting element ED.

Although it is shown in FIG. 7B that the first initialization thin-film transistor T4 and the second initialization thin-film transistor T7 are respectively connected to the previous scan line SL−1 and the next scan line SL+1, embodiments of the present disclosure are not necessarily limited thereto. For example, in an embodiment, both the first initialization thin-film transistor T4 and the second initialization thin-film transistor T7 may be connected to the previous scan line SL−1 and thus driven according to a previous scan signal Sn−1.

Another electrode of the storage capacitor Cst may be connected to the driving voltage line PL. One of the electrodes of the storage capacitor Cst may be connected to the gate electrode of the driving thin-film transistor T1, the drain electrode of the compensation thin-film transistor T3, and the source electrode of the first initialization thin-film transistor T4 together.

An opposite electrode (e.g., a cathode) of the light-emitting element ED is configured to receive a common voltage ELVSS. The light-emitting element ED may be configured to emit light by receiving the driving current from the driving thin-film transistor T1.

However, the pixel circuit PC is not necessarily limited to the number of thin-film transistors, the number of storage capacitors, and the circuit design described with reference to FIGS. 7A and 7B, and the number of thin-film transistors, the number of storage capacitors, and the circuit design may be variously changed.

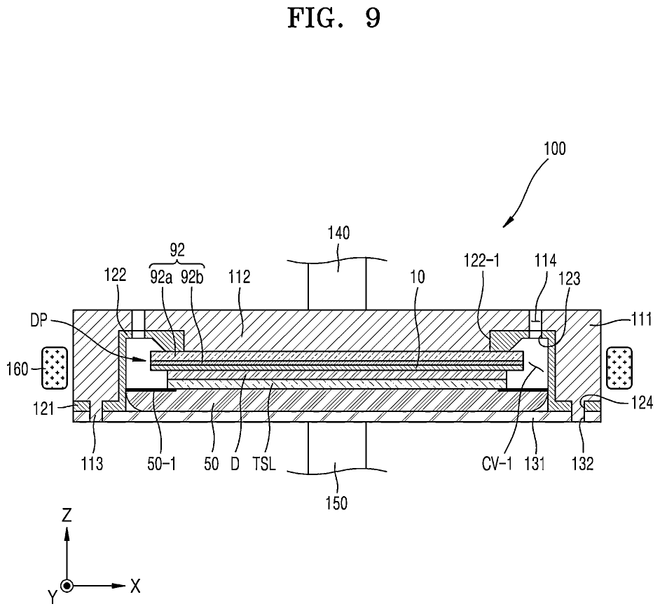

FIG. 8 is a schematic perspective view of an apparatus for manufacturing a display apparatus according to an embodiment. FIG. 9 is a schematic cross-sectional view of the apparatus for manufacturing a display apparatus shown in FIG. 8.

Referring to FIGS. 8 and 9, in an embodiment the apparatus for manufacturing a display apparatus may include a first jig 110, a mold 120, a second jig 130, a driver, and a light source 160.

The first jig 110 may include a first jig body 111, a pressing portion 112, a coupling portion 113, and a first injector 114. The pressing portion 112 may protrude from the first jig body 111 (e.g., downwardly protrude in the Z direction). In an embodiment, the pressing portion 112 may be in direct contact with a portion of the display panel DP to apply force to a portion of the display panel DP. The coupling portion 113 may protrude from the first jig body 111. In an embodiment, the coupling portion 113 may be formed in the form of a pin to protrude from the first jig body 111. In an embodiment, the coupling portion 113 may be provided in plurality, and the plurality of coupling portions 113 may be arranged at edge portions of the first jig body 111 to be spaced apart from each other. The first injector 114 may be disposed on the first jig body 111. In an embodiment, at least one first injector 114 may be provided. In an embodiment in which a plurality of first injectors 114 are provided, the plurality of first injectors 114 may be arranged to be spaced apart from each other. The first injector 114 may be connected to a separate supply unit and pipe configured to supply photocurable resin from the outside, or include a nozzle configured to spray photocurable resin which may be inserted to the first jig body 111.

The mold 120 may move together with the first jig 110 or be selectively coupled to the first jig 110. In an embodiment, the mold 120 may include a mold body 121, a protrusion portion 122, a second injector 123, and a first receiver 124. In an embodiment, the mold body 121 may have a plate shape and be closely attached to the second jig 130 and be selectively in direct contact with the second jig 130. The protrusion portion 122 may protrude from the mold body 121 towards the first jig 110 (e.g., upwardly in the Z direction). In an embodiment, the protrusion portion 122 may include an opening region 122-1, and the opening region 122-1 may be inserted to the pressing portion 112. In this embodiment, the pressing portion 112 may pass through the opening region 122-1 and be in direct contact with the display panel DP. The second injector 123 may be arranged to correspond to the first injector 114. The second injector 123 may be disposed on (e.g., directly thereon) the protrusion portion 122. The first receiver 124 may be arranged to correspond to the coupling portion 113. In an embodiment, the first receiver 124 may be formed in the form of a hole.

The second jig 130 may be arranged to receive the display panel DP. The second jig 130 may include a second jig body 131 having a plate shape and a second receiver 132 to which the coupling portion 113 is inserted. The second receiver 132 may be arranged in the second jig body 131 to correspond to the coupling portion 113 and the first receiver 124. In an embodiment, a portion of the coupling portion 113 protruding to pass through the first receiver 124 may be inserted to the second receiver 132.

The driver may be connected to at least one of the first jig 110 and the second jig 130 and may linearly move the at least one of the first jig 110 and the second jig 130. As an example, the driver may be connected to the first jig 110 and may bring the first jig 110 closer to the second jig 130 or separate the first jig 110 from the second jig 130. However, embodiments of the present disclosure are not necessarily limited thereto. For example, in an embodiment, the driver may be connected to the second jig 130 and may bring the second jig 130 closer to the first jig 110 or separate the second jig 130 from the first jig 110. In an embodiment, the driver may include a first driver 140 connected to the first jig 110, and a second driver 150 connected to the second jig 130. Hereinafter, for convenience of description, an embodiment in which the driver includes the first driver 140 and the second driver 150 is mainly described in detail.

The driver may be formed in various forms. As an example, in an embodiment the driver may include a cylinder. However, embodiments of the present disclosure are not necessarily limited thereto. For example, in an embodiment, the driver may include a linear motor. In an embodiment, the driver may include a motor and a ball screw connected to the motor. However, the driver is not necessarily limited thereto and may include all apparatuses and structures connected to at least one of the first jig 110 and the second jig 130 to move the at least one of the first jig 110 and the second jig 130.

The light source 160 may be disposed on the lateral surface of the display panel DP to irradiate light to the lateral surface of the display panel DP. In an embodiment, the light source 160 may be configured to emit visible light to the outside (e.g., the external environment). In an embodiment, the light source 160 may be configured to supply light with a peak top of a wavelength ranging from about 450 nm to about 500 nm. The light source 160 may have various forms. As an example, the light source 160 may be a point light source form. However, embodiments of the present disclosure are not necessarily limited thereto. For example, in an embodiment, the light source 160 may be disposed on a portion of the lateral surface of the display panel DP and be linearly formed. The light source 160 may be arranged to surround the entire lateral surface of the display panel DP.

The operation of the apparatus for manufacturing the display apparatus is described. In an embodiment, the display panel DP may be disposed on the second jig 130, and then the first jig 110 and the mold 120 may be disposed on the display panel DP. In an embodiment, at least one of the first driver 140 and the second driver 150 may be configured to dispose the first jig 110 and the second jig 130 such that the first jig 110 and the second jig 130 are initially spaced apart from each other. In addition, the mold 120 may be in a state of being coupled to the first jig 110, or only the mold 120 may be separately disposed on the display panel DP. In this embodiment, the first receiver 124 and the second receiver 132 may be disposed in the mold 120 and the second jig 130 to correspond to each other.

At least one of the first driver 140 and the second driver 150 may operate to then bring the first jig 110 and the second jig 130 closer to each other. In this embodiment, the first jig 110 may be closely attached to the second jig 130. The pressing portion 112 may be inserted into the opening region 122-1 to be in direct contact with the display panel DP and be configured to prevent the display panel DP from moving by applying force to the display panel DP. In addition, since the coupling portion 113 is inserted into the first receiver 124 and the second receiver 132, the coupling may be configured to prevent the mold 120 from moving and prevent the first jig 110 and the second jig 130 from moving relative to each other.

When the above process is completed, the mold 120, the second jig 130, and the display panel DP may form a first space CV-1. Photocurable resin may be injected to the first space CV-1 through the first injector 114 and the second injector 123 communicating with the first space CV-1. In an embodiment, the light source 160 may be configured to then irradiate light to the entire lateral surface of the first jig 110 and the mold 120 to cure photocurable resin. In this embodiment, the first jig 110 and the mold 120 may each include a transparent material. As an example, the first jig 110 may include at least one of polymethyl methacrylate (PMMA), polycarbonate (PC), glass and quartz which are transparent materials. In addition, the mold 120 may include at least one of silicon rubber, plastic rubber, and Teflon rubber which are elastic and transparent.

When the curing of the photocurable resin is completed by irradiation of light, at least one of the first driver 140 and the second driver 150 may be operated to separate the first jig 110 and the second jig 130 from each other. For example, in an embodiment the mold 120 may move together with the first jig 110 and be separated from the second jig 130, or the first jig 110 may be separated from the mold 120 and then the mold 120 may be separately removed.

Although it is described that the coupling portion 113 is provided to the first jig 110, embodiments of the present disclosure are not necessarily limited thereto. For example, in an embodiment, the coupling portion 113 may be disposed on the second jig 130, and the second receiver 132 may be disposed in the first jig 110. In an embodiment, the coupling portion 113 may be disposed on the mold 120, the first receiver 124 may be disposed in the first jig 110, and the second receiver 132 may be disposed in the second jig. In this embodiment, the coupling portion 113 of the mold 120 may include a first coupling portion protruding toward the first jig 110, and a second coupling portion protruding toward the second jig 130.

Hereinafter, a method of forming the first protective layer and the second protective layer is described in detail.

FIG. 10A to 10C are schematic cross-sectional views showing a method of manufacturing a display apparatus according to embodiments of the present disclosure.

Referring to FIGS. 10A to 10C, the display panel in which the substrate 10 including the bending protective layer is bent is prepared, and then, as described with reference to FIGS. 8 and 9, the first jig 110, the mold 120, and the second jig 130 are coupled to each other, and then, the photocurable resin may be supplied to the first space CV-1 and the second space CV-2.

For example, in an embodiment the photocurable resin may enter the inside of the first space CV-1 through the first injector 114 of the first jig 110 and the second injector 123 of the mold 120. In an embodiment, the first space CV-1 is formed by the mold 120, the second jig 130, the bending protective layer BPL, the touch sensor layer TSL, the display layer D, and at least a portion of the substrate 10, or formed by the second jig 130, the touch sensor layer TSL, the display layer D, and at least a portion of the substrate 10. In this embodiment, the photocurable resin may move from a portion of the lateral surface of the display panel DP to another lateral surface of the display panel DP. In addition, the photocurable resin may be inserted into the second space CV-2 formed by the protective film 92 and the cushion layer 91. For example, the second space CV-2 may be between upper and lower surfaces of the display panel DP in the bent area BA which face each other. In an embodiment, the protective film 92 includes the protective film base 92a and the adhesive layer 92b disposed in the bent area of the display panel DP.

In an embodiment, the light source 160 may be configured to then irradiate light from the outside of the first jig 110 and the mold 120 to the lateral surface of the display panel DP. The light may cure the photocurable resin disposed in the first space CV-1.

Light irradiated to the bent area of the display panel DP may cure not only the photocurable resin in the first space CV-1 arranged outside the bent area but also the photocurable resin disposed in the second space CV-2. In an embodiment, due to the substrate 10 disposed between the first space CV-1 and the second space CV-2, light is not nearly blocked but may pass through the substrate 10 and be transferred to the photocurable resin inside the second space CV-2.

In this embodiment the photocurable resin disposed in the second space CV-2 may form the second protective layer 93b, and the photocurable resin disposed in the first space CV-1 may form the first protective layer 93a. For example, in an embodiment the first protective layer 93a may be disposed on the edge and the bending protective layer BPL of the display panel DP. In addition, the first protective layer 93a may be integrally formed with the second protective layer 93b by being connected to the second protective layer 93b. In an embodiment, the first protective layer 93a and the second protective layer 93b on the lateral surface of the display panel DP may be connected to each other.

Accordingly, the apparatus for manufacturing the display apparatus and the method of manufacturing the display apparatus may be configured to form the first space CV-1 and the second space CV-2 simultaneously. In addition, the apparatus for manufacturing the display apparatus and the method of manufacturing the display apparatus may be configured to reduce time required to form the protective layer by forming the protective layer using light. Since the apparatus for manufacturing the display apparatus and the method of manufacturing the display apparatus do not need to apply excessive energy when forming the protective layer, damage to various elements of the display panel when forming the protective layer may be reduced.

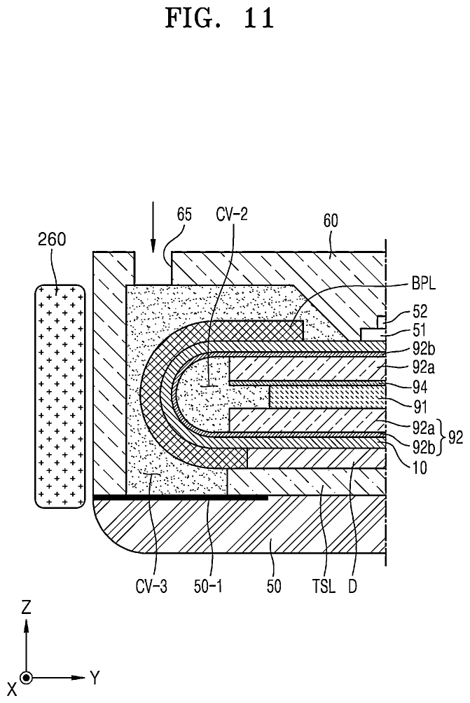

FIG. 11 is a schematic cross-sectional view of a portion of the display apparatus according to an embodiment.

Referring to FIG. 11, in an embodiment the display apparatus may include the display panel, the display circuit board 51, the cover member 50, the bracket 60, the main circuit board, and the lower cover. In this embodiment, since the display panel, the display circuit board 51, the cover member 50, the main circuit board, and the lower cover are similar to those described with reference to FIGS. 1 to 3B, detailed descriptions thereof are omitted for economy of description.

In an embodiment, the bracket 60 may include a third injector 65 (e.g., an injection hole) through which the photocurable resin is injected. In this embodiment, the third injector 65 may be formed to pass through the backside (e.g., a surface facing the lower cover) of the bracket 60. In an embodiment, the third injector 65 may be configured to communicate with a third space CV-3 formed by at least one edge of the display panel DP, the bracket 60, and the cover member 50. In this embodiment, the third space CV-3 may be defined by the substrate 10 on which the bending protective layer BPL and the display layer D are disposed, the touch sensor layer TSL disposed on the display layer D, and the bracket 60. At least one third injector 65 may be provided. In an embodiment in which the plurality of third injectors 65 are provided, the plurality of third injectors 65 may be spaced apart from each other.

In an embodiment, the display panel DP is manufactured, then the cover member 50 may be attached to the display panel DP, the display panel DP may be inserted into the bracket 60, and the cover member 50 may be coupled to the bracket 60. In an embodiment, the cover member 50 may be coupled to the bracket 60 through separate resin or a separate adhesive layer. In addition, the display panel DP inserted to the bracket 60 may be bent as shown in FIG. 5. The display circuit board 51 and the display driver 52 may be attached to the bracket 60 or inserted into the bracket 60.

The display panel DP is disposed inside the bracket 60, and then the photocurable resin may be supplied through the third injector 65. In an embodiment, the photocurable resin may be injected to the third space CV-3 including a receiving space formed in the bracket 60, and the photocurable resin may spread to the entire edge of the display panel DP. In an embodiment, a portion of the photocurable resin may move to the second space CV-2 shown in FIG. 5 to fill the inside of the second space CV-2. The second space CV-2 may be defined by the protective film 92 including the protective film base 92a and the adhesive layer 92b, and the cushion layer 91.

After the above process is completed, light may be irradiated by a light source 260 from the outside of the bracket 60. Since descriptions of the photocurable resin and light are the same as or similar to those described with reference to FIGS. 1 to 3B, and 8, detailed descriptions thereof are omitted for economy of explanation.

In an embodiment, the bracket 60 may include a transparent material through which light may pass. As an example, the bracket 60 may include at least one of polymethyl methacrylate (PMMA), polycarbonate (PC), glass, quartz, and transparent silicon rubber which are transparent materials.

In an embodiment in which light is transmitted as described above, the first protective layer 93a may be formed between the display panel DP and the bracket 60, and the second protective layer 93b may be formed inside the bent area BA of the display panel DP. In this embodiment, the first protective layer 93a and the second protective layer 93b may be connected to each other.

Accordingly, since the display apparatus includes the first protective layer 93a and the second protective layer 93b, damage to the display panel caused by impacts applied to not only the bent area of the display panel DP but also the edge of the display panel DP may be reduced.

In addition, according to a method of manufacturing the display apparatus, the protective layer may be formed using a relatively swift and simple process.

The display apparatus according to embodiments of the present disclosure may be configured to protect the edge of the display panel and reduce destruction of the bent portion of the display panel.

The apparatus of manufacturing the display apparatus and the method of manufacturing the display apparatus may be configured to simultaneously form the protective layers on the lateral surface and the bent portion of the display panel.

The apparatus of manufacturing the display apparatus and the method of manufacturing the display apparatus may be configured to relatively swiftly manufacture the display apparatus by using light.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the present disclosure.

What is claimed is:

1. A display apparatus including a display panel, wherein the display panel comprises:
a substrate including a first area, a second area, and a bent area that is in a bent state, the bent area connecting the first area to the second area;
a first protective layer disposed inside the bent area of the substrate; and
a second protective layer disposed on at least a portion of an edge of the substrate and at least one surface of the bent area of the substrate.

2. The display apparatus of claim 1, wherein the first protective layer and the second protective layer each include a photocurable resin.

3. The display apparatus of claim 2, wherein the photocurable resin is cured by light with a peak top of a wavelength in a range of about 450 nm to about 500 nm.

4. The display apparatus of claim 2, wherein the photocurable resin includes at least one of diphenyl (2,4,6-trimethylbenzoyl) phosphine oxide (2,4,6-trimethylbenzoyldiphenyl phosphine oxide), ethyl (2:4 6-trimethylbenzoyl)phenylphosphophinate (ethyl (2,4,6-trimethylbenzoyl)phenylphosphinate), bis-acylphosphine oxides, and bis(cyclopentadienyl)-bis(2,6-difluoro-3-(pyrrol-1-yl))-phenyl) titanium (bis(cyclopentadienyl)-bis [2,6-difluoro-3-(pyrrol-1-yl)-phenyl]titaninum) and camphoquinone (CQ).

5. The display apparatus of claim 2, further comprising a bracket, wherein the bracket is arranged to receive the display panel.

6. The display apparatus of claim 5, wherein the bracket includes an injection hole through that is arranged to receive the photocurable resin.

7. The display apparatus of claim 5, wherein the bracket includes a transparent material.

8. The display apparatus of claim 1, wherein the second protective layer is connected to the first protective layer.

9. An apparatus for manufacturing a display apparatus, the apparatus comprising:
a first jig;
a second jig arranged to receive a display panel thereon, the second jig facing the first jig; and
a mold disposed between the first jig and the second jig, the mold is selectively coupled to the first jig, the mold and the second jig together forming a space in an edge portion of the display panel,
wherein the first jig and the mold include a transparent material.

10. The apparatus of claim 9, wherein:
one of the first jig and the second jig includes a coupling portion; and
another of the first jig and the second jig includes a first receiver that is arranged to receive the coupling portion.

11. The apparatus of claim 10, wherein the mold includes a second receiver that is arranged to receive the coupling portion.

12. The apparatus of claim 9, wherein the first jig and the mold include an injector that is arranged to receive a photocurable resin in the space.

13. The apparatus of claim 12, wherein the photocurable resin is cured by light with a peak top of a wavelength in a range of about 450 nm to about 500 nm.

14. The apparatus of claim 12, wherein the photocurable resin includes at least one of diphenyl (2,4,6-trimethylbenzoyl) phosphine oxide (2,4,6-trimethylbenzoyldiphenyl phosphine oxide), ethyl (2:4 6-trimethylbenzoyl)phenylphosphophinate (ethyl (2,4,6-trimethylbenzoyl)phenylphosphinate), bis-acylphosphine oxides, and bis(cyclopentadienyl)-bis(2,6-difluoro-3-(pyrrol-1-yl))-phenyl) titanium (bis(cyclopentadienyl)-bis [2,6-difluoro-3-(pyrrol-1-yl)-phenyl]titaninum) and camphoquinone (CQ).

15. The apparatus of claim 9, further comprising a light source disposed on a lateral surface of the first jig and the mold and irradiating light to the space.

16. The apparatus of claim 15, wherein the light source irradiates visible light towards the first jig and the mold.

17. A method of manufacturing a display apparatus, the method comprising:
disposing, on a second jig, a display panel having a bent portion that is in a bent state;
disposing, on the display panel, a first jig and a mold to form a first space in at least one edge of the display panel;
supplying a photocurable resin into the first space; and
curing the photocurable resin by irradiating light to the first space.

18. The method of claim 17, wherein the photocurable resin is cured by light with a peak top of a wavelength in a range of about 450 nm to about 500 nm.

19. The method of claim 17, wherein the photocurable resin includes at least one of diphenyl (2,4,6-trimethylbenzoyl) phosphine oxide (2,4,6-trimethylbenzoyldiphenyl phosphine oxide), ethyl (2:4 6-trimethylbenzoyl)phenylphosphophinate (ethyl (2,4,6-trimethylbenzoyl)phenylphosphinate), bis-acylphosphine oxides, and bis(cyclopentadienyl)-bis(2,6-difluoro-3-(pyrrol-1-yl))-phenyl) titanium (bis(cyclopentadienyl)-bis [2,6-difluoro-3-(pyrrol-1-yl)-phenyl]titaninum) and camphoquinone (CQ).

20. The method of claim 17, wherein the light is irradiated from a lateral surface of the display panel.

21. The method of claim 17, further comprising injecting the photocurable resin into a second space between upper and lower surfaces of the bent portion of the display panel facing each other.

22. The method of claim 21, wherein the photocurable resin supplied into the first space and the photocurable resin injected into the second space are cured and connected to each other.

23. A method of manufacturing a display apparatus, the method comprising:
disposing a display panel inside a bracket to form a first space defined by at least one edge of the display panel, the bracket and a cover member of the display panel;
supplying a photocurable resin into the first space; and
curing the photocurable resin by irradiating light to the first space.

24. The method of claim 23, wherein the photocurable resin is cured by light with a peak top of a wavelength in a range of about 450 nm to about 500 nm.

25. The method of claim 23, wherein the photocurable resin includes at least one of diphenyl (2,4,6-trimethylbenzoyl) phosphine oxide (2,4,6-trimethylbenzoyldiphenyl phosphine oxide), ethyl (2:4 6-trimethylbenzoyl)phenylphosphophinate (ethyl (2,4,6-trimethylbenzoyl)phenylphosphinate), bis-acylphosphine oxides, and bis(cyclopentadienyl)-bis(2,6-difluoro-3-(pyrrol-1-yl))-phenyl) titanium (bis(cyclopentadienyl)-bis [2,6-difluoro-3-(pyrrol-1-yl)-phenyl]titaninum) and camphoquinone (CQ).

26. The method of claim 23, wherein the light is irradiated from a lateral surface of the display panel.

27. The method of claim 23, further comprising injecting the photocurable resin into a second space between opposing upper and lower surfaces of a bent portion of the display panel that is in a bent state.

28. The method of claim 27, further comprising the photocurable resin supplied into the first space and the photocurable resin injected into the second space are cured and connected to each other.

29. The method of claim 23, wherein the bracket includes a transparent material.
